(19) United States
(12) Patent Application Publication
(10) Pub. No.: US 2026/0303089 A1
(43) Pub. Date: Oct. 1, 2026

(54) SEMICONDUCTOR DEVICE

(71) Applicants: KABUSHIKI KAISHA TOSHIBA, Kawasaki-shi (JP); Toshiba Electronic Devices & Storage Corporation, Kawasaki-shi (JP)

(72) Inventors: Reiji TAGOMORI, Yokohama (JP); Shoji OOTAKA, Yokohama (JP); Yoshiharu NITO, Yokohama (JP); Satoru OSHITA, Hadano (JP)

(73) Assignees: KABUSHIKI KAISHA TOSHIBA, Kawasaki-shi (JP); Toshiba Electronic Devices & Storage Corporation, Kawasaki-shi (JP)

(21) Appl. No.: 19/373,946

(22) Filed: Oct. 30, 2025

(30) Foreign Application Priority Data
Mar. 25, 2025 (JP) 2025-049750

(51) Int. Cl. H03K 17/687; H03K 17/14

(52) U.S. Cl. CPC H03K 17/687; H03K 17/145

(57) ABSTRACT

According to one embodiment, a semiconductor device includes a first table including driving patterns, a controller including the first table, and a driver. The driver includes a second table including first and second patterns, a control circuit, a generation circuit, and a drive circuit that drives a switch element. At a timing when the switch element is turned on or off, in a case where a change amount of first information of the switch element is less than a first threshold, the control circuit generates a correction value, and the generation circuit generates a driving pulse based on the first pattern and the correction value, and in a case where the change amount is equal to or greater than the first threshold, the control circuit replaces the first pattern with the second pattern, and the generation circuit generates the driving pulse based on the replaced first pattern.

### CROSS-REFERENCE TO RELATED APPLICATION

This application is based upon and claims the benefit of priority from Japanese Patent Application No. 2025-049750, filed Mar. 25, 2025, the entire contents of which are incorporated herein by reference.

### FIELD

Embodiments described herein relate generally to a semiconductor device.

### BACKGROUND

A semiconductor device including a gate driver that drives a switch element (hereinafter, also referred to as a “power switch”) used for a power device is known. In such a semiconductor device, in a case where the gate driver drives the power switch fast, the switching loss decreases and the overall efficiency increases. However, a large surge (ringing) occurs. The surge causes noise. On the other hand, in a case where the gate driver drives the power switch slowly, the surge is reduced. However, the switching loss increases and the overall efficiency decreases. As described above, reduction of the surge and reduction of the switching loss are in a trade-off relationship.

In recent years, as a technique for controlling driving of a power switch by a gate driver, there is a technique called active gate control. This is a technique in which switching of the power switch is not simply turned on or off, but the intensity of driving at the time of an on state is changed with time. For example, a driving pattern of a gate of the power switch is generated as a specific waveform that improves the trade-off, and the power switch is driven based on the waveform. With this technique, the relationship between the surge and the switching loss, which has been in a trade-off relationship, can be improved and both reduction of the surge and reduction of the switching loss can be achieved. However, in order to cope with changes in the load current flowing to the load in the system including the power device, the power supply voltage supplied to the power switch, and the temperature of the power device, more driving patterns are needed and the memory capacity increases.

### BRIEF DESCRIPTION OF DRAWINGS

FIG. 1 is a block diagram showing an example of a hardware configuration of a semiconductor device according to a first embodiment.

FIG. 2 is a timing chart illustrating an example of an operation in a case where a switch element in a system including a power device is turned on by normal gate control in a semiconductor device of a comparative example.

FIG. 3 is a timing chart illustrating an example of an operation in a case where a switch element in a system including a power device is turned on by active gate control in the semiconductor device according to the first embodiment.

FIG. 4 is a timing chart illustrating an example of an operation in a case where a switch element in a system including a power device is turned off by normal gate control in a semiconductor device of a comparative example.

FIG. 5 is a timing chart illustrating an example of an operation in a case where the switch element in the system including the power device is turned off by the active gate control in the semiconductor device according to the first embodiment.

FIG. 6 is a diagram illustrating an example of brake voltage supply timing according to a drain current in a case where the switch element is turned on by the active gate control of the semiconductor device according to the first embodiment.

FIG. 7 is a diagram illustrating an example of the brake voltage supply timing according to the drain current in a case where the switch element is turned off by the active gate control of the semiconductor device according to the first embodiment.

FIG. 8 is a diagram illustrating an example of the brake voltage supply timing according to a drain voltage in a case where the switch element is turned on by the active gate control of the semiconductor device according to the first embodiment.

FIG. 9 is a diagram illustrating an example of the brake voltage supply timing according to the drain voltage in a case where the switch element is turned off by the active gate control of the semiconductor device according to the first embodiment.

FIG. 10 is a diagram illustrating an example of the brake voltage supply timing according to a temperature in a case where the switch element is turned on by the active gate control of the semiconductor device according to the first embodiment.

FIG. 11 is a diagram illustrating an example of the brake voltage supply timing according to the temperature in a case where the switch element is turned off by the active gate control of the semiconductor device according to the first embodiment.

FIG. 12 is a conceptual diagram showing an example of a lookup table used in the semiconductor device according to the first embodiment.

FIG. 13 is a conceptual diagram showing an example of a lookup table stored in a memory in a gate driver included in the semiconductor device according to the first embodiment.

FIG. 14 is a block diagram showing an example of a functional configuration of a control circuit in the gate driver included in the semiconductor device according to the first embodiment.

FIG. 15 is a diagram illustrating an example of a configuration of the lookup table in the gate driver included in the semiconductor device according to the first embodiment.

FIG. 16 is a circuit diagram showing an example of a configuration of a generation circuit in the gate driver included in the semiconductor device according to the first embodiment.

FIG. 17 is a diagram showing an example of a waveform of a driving pulse generated by the generation circuit in the gate driver included in the semiconductor device according to the first embodiment.

FIG. 18 is a flowchart showing an example of an active gate control operation of the semiconductor device according to the first embodiment.

FIG. 19 is a flowchart showing an example of the active gate control operation of the semiconductor device according to the first embodiment.

FIG. 20 is a flowchart showing an example of the active gate control operation of the semiconductor device according to the first embodiment.

FIG. 21 is a flowchart showing an example of the active gate control operation of the semiconductor device according to the first embodiment.

FIG. 22 is a diagram illustrating an example of a configuration of a lookup table in a gate driver included in a semiconductor device according to a second embodiment.

FIG. 23 is a diagram illustrating an example of a configuration of a lookup table in a gate driver included in a semiconductor device according to a third embodiment.

FIG. 24 is a circuit diagram showing an example of a configuration of a generation circuit in the gate driver included in the semiconductor device according to the third embodiment.

FIG. 25 is a diagram showing an example of a waveform of a driving pulse generated by the generation circuit in the gate driver included in the semiconductor device according to the third embodiment.

FIG. 26 is a diagram showing an example of a waveform of a driving pulse generated by the generation circuit in the gate driver included in the semiconductor device according to the third embodiment.

FIG. 27 is a diagram showing an example of a waveform of a driving pulse generated by the generation circuit in the gate driver included in the semiconductor device according to the third embodiment.

### DETAILED DESCRIPTION

In general, according to one embodiment, a semiconductor device includes a first table including a plurality of driving patterns, a controller including the first table, and a driver. The driver includes a second table including at least a first pattern and a second pattern of the plurality of the driving patterns in the first table, a control circuit, a generation circuit that generates a driving pulse based on the first pattern, and a drive circuit that drives a switch element by a voltage or a current based on the first pattern at a timing based on the driving pulse. At a timing when the switch element is turned on or off, in a case where a change amount of first information of the switch element is less than a first threshold, the control circuit generates a correction value, and the generation circuit generates the driving pulse based on the first pattern and the correction value, and in a case where the change amount of the first information of the switch element is equal to or greater than the first threshold, the control circuit replaces the first pattern with the second pattern, and the generation circuit generates the driving pulse based on the replaced first pattern.

Hereinafter, embodiments will be described with reference to the drawings. In the following description, components having substantially the same functions and configurations are denoted by the same reference numerals, and repeated description may be omitted. In a case where the components having similar configurations are particularly distinguished from each other, different characters or numbers may be added to the end of the same reference numeral. All descriptions about one embodiment also apply as descriptions about another embodiment unless expressly or explicitly excluded.

### 1. First Embodiment

A semiconductor device according to a first embodiment will be described. Hereinafter, a semiconductor device including a gate driver that drives a power switch will be described as an example. The semiconductor device according to the present embodiment is applied to, for example, driving of a power switch used for an in-vehicle traction inverter or the like.

### 1.1 Configuration

### 1.1.1 Hardware Configuration of Semiconductor Device

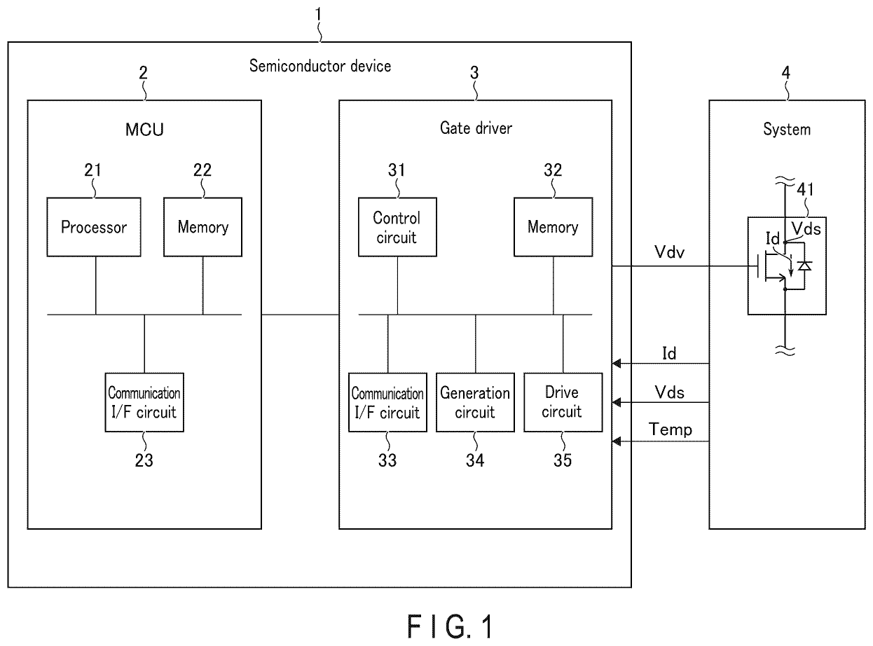

A hardware configuration of a semiconductor device 1 according to the first embodiment will be described with reference to FIG. 1. FIG. 1 is a block diagram showing an example of a hardware configuration of the semiconductor device 1 according to the present embodiment.

The semiconductor device 1 is a device that controls a switch element (power switch) 41 in a system 4 including a power device. Hereinafter, the system 4 including the power device is also simply referred to as a “system 4”. The semiconductor device 1 is, for example, an integrated circuit (IC) chip. The semiconductor device 1 is connected to the system 4 via a bus.

The semiconductor device 1 controls the turn-on and turn-off of the switch element 41 by supplying a driving voltage Vdv to the switch element 41 based on a driving pattern of active gate control. FIG. 1 illustrates a case where the switch element 41 is controlled by voltage (voltage drive). The switch element 41 is, for example, a metal oxide semiconductor field effect transistor (MOSFET), an insulated gate bipolar transistor (IGBT), or the like. Examples of the MOSFET used as the switch element 41 include, for example, a silicon carbide (SiC) MOSFET. In the example of FIG. 1, the switch element 41 is an n-channel MOSFET. The switch element 41 constitutes an inverter circuit in the system 4 including the power device. One end or the other end of the switch element 41 is connected to a load (not illustrated) in the system 4 including the power device. The load is, for example, a motor.

In addition, the semiconductor device 1 acquires a value of a drain current Id of the switch element 41, a value of a drain-source voltage Vds (hereinafter, referred to as “drain voltage Vds”) of the switch element 41, and a value of a temperature Temp of the system 4 (switch element 41) from the system 4. The drain current Id corresponds to, for example, a current (load current) flowing through the load in the system 4. The drain voltage Vds corresponds to, for example, a power supply voltage supplied to the system 4 (switch element 41). The temperature Temp is detected by, for example, a temperature sensor (not illustrated) in the system 4. The semiconductor device 1 maintains or changes a driving pattern for controlling turn-on and turn-off of the switch element 41 based on the drain current Id, the drain voltage Vds, and the temperature Temp. Hereinafter, the value of the drain current Id, the value of the drain voltage Vds, and the value of the temperature Temp are also collectively referred to as “system information INF”.

As illustrated in FIG. 1, the semiconductor device 1 includes, for example, a micro controller unit (MCU) 2 and a gate driver 3. Hereinafter, the MCU 2 is also referred to as a “controller 2”. The gate driver 3 is also referred to as a “driver circuit 3”.

The MCU 2 is a device that controls the gate driver 3. The MCU 2 is connected to the gate driver 3 via a bus. The MCU 2 includes, for example, a processor 21, a memory 22, and a communication interface (I/F) circuit 23.

The processor 21 is, for example, a central processing unit (CPU). The processor 21 executes various control processes. The processor 21 executes, for example, a driving pattern transfer process and a drive instruction process. The driving pattern transfer process is a process of acquiring one or more driving patterns from a lookup table LUT to be described later based on the system information INF received from the system 4 via the gate driver 3, and transmitting the acquired driving patterns to the gate driver 3. The drive instruction process is a process of transmitting a clock signal and a pulse width modulation (PWM) signal instructing turn-on or turn-off of the switch element 41 to the gate driver 3. Hereinafter, the clock signal is referred to as a “signal CLK”. The PWM signal is referred to as a “signal PWM”.

The memory 22 includes, for example, a read only memory (ROM) and a random access memory (RAM). The ROM stores, for example, programs for causing the processor 21 to execute various control processes including the driving pattern transfer process and the drive instruction process. In addition, the ROM stores the lookup table LUT. The RAM is used as a work area of the processor 21. The RAM temporarily stores, for example, the above-described programs executed by the processor 21, data at the time of executing the above-described processes, and the like.

The communication interface circuit 23 is a circuit that manages communication between the MCU 2 and the gate driver 3. The communication interface circuit 23 transmits signals such as the signals CLK and PWM and data such as one or more driving patterns to the gate driver 3. The communication interface circuit 23 receives data such as the system information INF from the gate driver 3.

The gate driver 3 is a device that drives the switch element 41. The gate driver 3 is connected to the system 4 via a bus. The gate driver 3 includes, for example, a control circuit 31, a memory 32, a communication interface (I/F) circuit 33, a generation circuit 34, and a drive circuit 35.

The control circuit 31 is a circuit that executes various control processes. The control circuit 31 is, for example, a CPU, a micro processing unit (MPU), a graphics processing unit (GPU), a field programmable gate array (FPGA), or the like. The control circuit 31 executes, for example, a system information acquisition process, a driving pattern load process, a system information determination process, a driving pattern correction process, and a driving pattern switching process. The system information acquisition process is a process of acquiring the system information INF from the system 4. The driving pattern loading process is a process of receiving one or more driving patterns from the MCU 2 and loading the received driving patterns into the memory 32. The system information determination process is a process of determining whether there is a change in the drain current Id, the drain voltage Vds, and the temperature Temp acquired from the system 4. The driving pattern correction process is a process of correcting the driving patterns. The driving pattern switching process is a process of switching the driving patterns. Details of the system information acquisition process, the driving pattern load process, the system information determination process, the driving pattern correction process, and the driving pattern switching process will be described later.

The memory 32 includes, for example, a ROM and a RAM. The ROM stores programs for causing the control circuit 31 to execute various control processes including, for example, the system information acquisition process, the driving pattern loading process, the system information determination process, the driving pattern correction process, and the driving pattern switching process. The RAM is used as a work area of the control circuit 31. The RAM temporarily stores, for example, the above-described programs executed by the control circuit 31, data at the time of executing the above-described processes, and the like. The driving pattern loaded by the driving pattern loading process is stored in the RAM.

The communication interface circuit 33 is a circuit that manages communication between the gate driver 3 and the MCU 2 and communication between the gate driver 3 and the system 4. The communication interface circuit 33 transmits data such as the system information INF to the MCU 2. The communication interface circuit 33 receives signals such as signals CLK and PWM and data such as one or more driving patterns from the MCU 2. In addition, the communication interface circuit 33 supplies the driving voltage Vdv to the system 4. The communication interface circuit 33 receives the system information INF from the system 4.

The generation circuit 34 is a circuit that generates a driving pulse (waveform) based on the driving patterns stored in the RAM in the memory 32. The driving pulse controls timing of supplying the driving voltage Vdv to the gate of the switch element 41.

The drive circuit 35 is a circuit that drives the switch element 41 by a voltage based on the driving patterns stored in the RAM in the memory 32 at timing based on the driving pulse.

### 1.1.2 Lookup Table LUT

The lookup table LUT will be described. The lookup table LUT is a table that stores the driving patterns of the active gate control. First, the active gate control will be described below.

### Active Gate Control

The active gate control will be described by comparing with normal gate control.

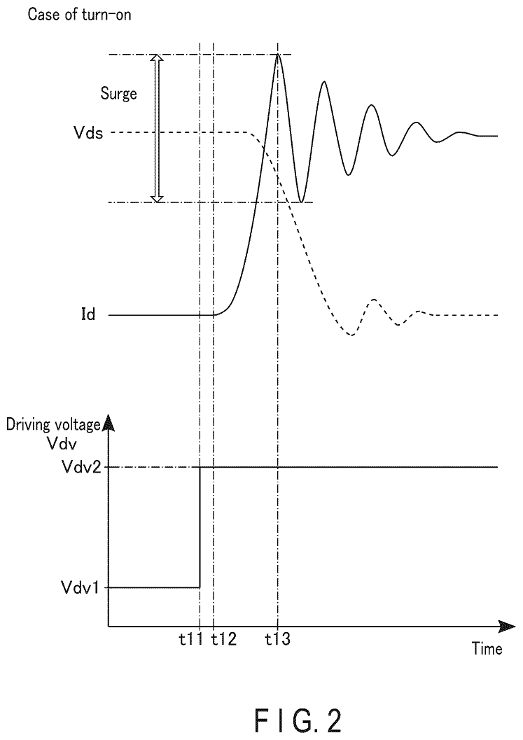

FIG. 2 is a timing chart illustrating an example of an operation in a case where the switch element 41 is turned on by the normal gate control in a semiconductor device of a comparative example. FIG. 2 illustrates changes in the drain current Id and the drain voltage Vds in a case where the driving voltage Vdv is under normal gate control. The drain current Id is indicated by the solid line, and the drain voltage Vds is indicated by the broken line.

Before time t11, the switch element 41 is in an off state. The driving voltage Vdv is a voltage Vdv1. The voltage Vdv1 is a voltage (for example, 0 V) that turns off the switch element 41. The drain current Id is, for example, 0 A. The drain voltage Vds is, for example, a voltage higher than 0 V, and is a power supply voltage applied to the power switch.

At time t11, the switch element 41 is turned on. Specifically, a voltage Vdv2 is supplied (applied) to the gate of the switch element 41. The voltage Vdv2 is a voltage (for example, a voltage higher than the voltage Vdv1) that turns on the switch element 41. As a result, a gate-source voltage Vgs (hereinafter, referred to as a “gate voltage Vgs”) of the switch element 41 increases. Note that, normally, the gate has a parasitic resistance (not illustrated), and the gate voltage Vgs and the voltage Vdv2 are not the same voltage immediately after the voltage Vdv2 is applied, but gradually approach each other.

At time t12, in a case where the gate voltage Vgs becomes equal to or higher than a threshold voltage Vth of the switch element 41, the drain current Id starts to flow through the switch element 41. In a case where the drain current Id increases, the drain voltage Vds starts to decrease.

At time t13, a large surge of the drain current Id is generated. Thereafter, the surge of the drain current Id decreases as the drain voltage Vds decreases, and finally converges. The drain voltage Vds also finally converges.

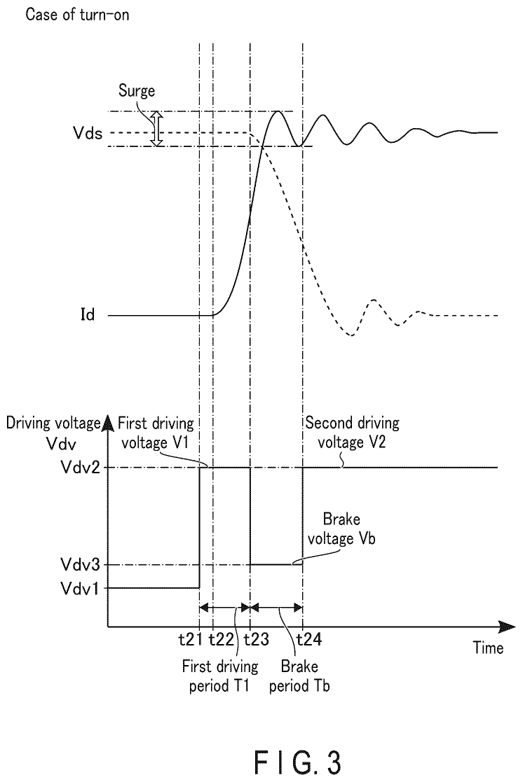

FIG. 3 is a timing chart illustrating an example of an operation in a case where the switch element 41 is turned on by the active gate control in the semiconductor device 1. FIG. 3 illustrates changes in the drain current Id and the drain voltage Vds in a case where the driving voltage Vdv is under the active gate control. The drain current Id is indicated by the solid line, and the drain voltage Vds is indicated by the broken line.

Before time t21, the switch element 41 is in an off state. The driving voltage Vdv is a voltage Vdv1. The voltage Vdv1 is a voltage (for example, 0 V) that turns off the switch element 41. The drain current Id is, for example, 0 A. The drain voltage Vds is, for example, a voltage higher than 0 V.

At time t21, the switch element 41 is turned on. Specifically, the voltage Vdv2 is supplied to the gate of the switch element 41. The voltage Vdv2 is a voltage (for example, a voltage higher than the voltage Vdv1) that turns on the switch element 41. As a result, the gate voltage Vgs of the switch element 41 increases.

At time t22, in a case where the gate voltage Vgs becomes equal to or higher than the threshold voltage Vth of the switch element 41, the drain current Id starts to flow through the switch element 41. In a case where the drain current Id increases, the drain voltage Vds starts to decrease.

At time t23, a voltage Vdv3 is supplied to the gate of the switch element 41 in order to suppress generation of a large surge generated after time t23. The voltage Vdv3 is a voltage (for example, a voltage higher than the voltage Vdv1 and lower than the voltage Vdv2) that turns on the switch element 41. As a result, the gate voltage Vgs of the switch element 41 decreases. The period (length) from time t22 to time t23 is shorter than the period from time t12 to time t13 illustrated in FIG. 2. That is, the voltage Vdv3 is supplied to the gate of the switch element 41 before the surge of the drain current Id occurs. As a result, the surge of the drain current Id is generated after the time t23, but the generated surge is small. Thereafter, the surge of the drain current Id decreases as the drain voltage Vds decreases. The lower the voltage Vdv3, the smaller the surge.

At time t24, the voltage Vdv2 is supplied to the gate of the switch element 41 to suppress the increase in conduction loss. As a result, the gate voltage Vgs of the switch element 41 increases, and the conduction loss decreases. In addition, although the gate voltage Vgs increases due to the supply of the voltage Vdv2, since the surge generated after time t23 is small, the surge of the drain current Id decreases as the drain voltage Vds decreases, and finally converges. The drain voltage Vds also finally converges. As the period from time t23 to time t24 is longer, the surge becomes smaller.

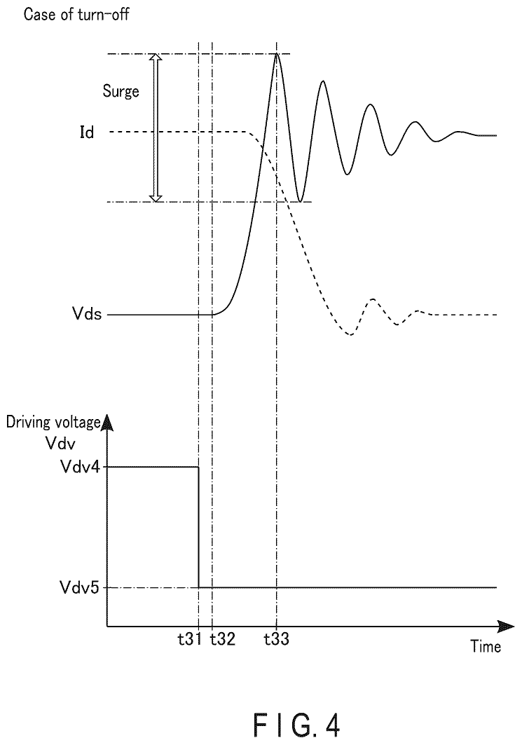

FIG. 4 is a timing chart illustrating an example of an operation in a case where the switch element 41 is turned off by the normal gate control in a semiconductor device of a comparative example. FIG. 4 illustrates changes in the drain current Id and the drain voltage Vds in a case where the driving voltage Vdv is under the normal gate control. The drain current Id is indicated by the broken line, and the drain voltage Vds is indicated by the solid line.

Before time t31, the switch element 41 is in an on state. The driving voltage Vdv is a voltage Vdv4. The voltage Vdv4 is a voltage (for example, a voltage higher than 0 V) that turns on the switch element 41. The drain current Id is, for example, a current higher than 0 A. The drain voltage Vds is, for example, 0 V.

At time t31, the switch element 41 is turned off. Specifically, a voltage Vdv5 is supplied to the gate of the switch element 41. The voltage Vdv5 is a voltage (for example, a voltage lower than the voltage Vdv4) that turns off the switch element 41. As a result, the gate-source voltage Vgs of the switch element 41 decreases.

At time t32, the drain voltage Vds starts to increase. Thereafter, the drain current Id starts to decrease.

At time t33, a large surge of the drain voltage Vds is generated. Thereafter, the surge of the drain voltage Vds decreases as the drain current Id decreases, and finally converges. The drain current Id also finally converges.

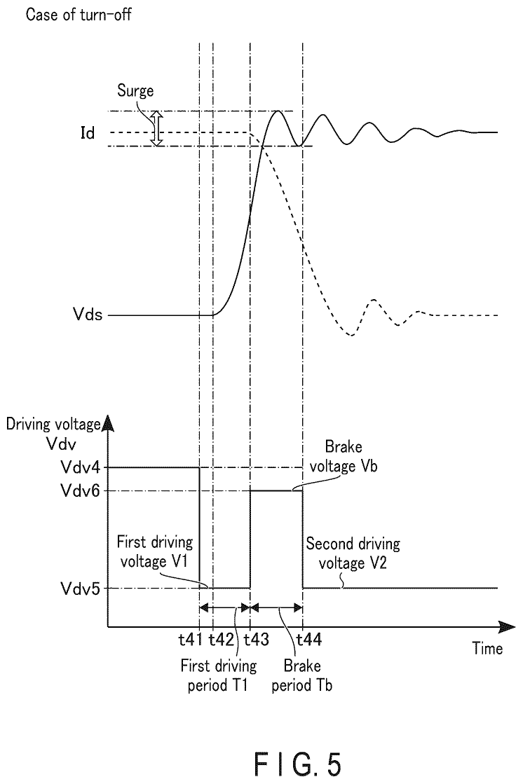

FIG. 5 is a timing chart illustrating an example of an operation in a case where the switch element 41 is turned off by the active gate control in the semiconductor device 1. FIG. 5 illustrates changes in the drain current Id and the drain voltage Vds in a case where the driving voltage Vdv is under the active gate control. The drain current Id is indicated by the broken line, and the drain voltage Vds is indicated by the solid line.

Before time t41, the switch element 41 is in an on state. The driving voltage Vdv is the voltage Vdv4. The voltage Vdv4 is a voltage (for example, a voltage higher than 0 V) that turns on the switch element 41. The drain current Id is, for example, a current higher than 0 A. The drain voltage Vds is, for example, 0 V.

At time t41, the switch element 41 is turned on. Specifically, the voltage Vdv5 is supplied to the gate of the switch element 41. The voltage Vdv5 is a voltage (for example, a voltage lower than the voltage Vdv4) that turns off the switch element 41. As a result, the gate voltage Vgs of the switch element 41 decreases.

At time t42, the drain voltage Vds starts to increase. Thereafter, the drain current Id starts to decrease.

At time t43, a voltage Vdv6 is supplied to the gate of the switch element 41 in order to suppress generation of a large surge generated after time t43. The voltage Vdv6 is a voltage (for example, a voltage higher than the voltage Vdv5 and lower than the voltage Vdv4) that turns off the switch element 41. As a result, the gate voltage Vgs of the switch element 41 increases. The period (length) from time t42 to time t43 is shorter than the period from time t32 to time t33 illustrated in FIG. 4. That is, the voltage Vdv6 is supplied to the gate of the switch element 41 before the surge of the drain voltage Vds occurs. As a result, the surge of the drain voltage Vds is generated after the time t43, but the generated surge is small. Thereafter, the surge of the drain voltage Vds decreases as the drain current Id decreases. The higher the voltage Vdv6, the smaller the surge.

At time t44, the voltage Vdv5 is supplied to the gate of the switch element 41 to suppress the increase in switching loss. As a result, the gate voltage Vgs of the switch element 41 decreases, and the switching loss decreases. In addition, although the gate voltage Vgs decreases due to the supply of the voltage Vdv5, since the surge generated after the time t43 is small, the surge of the drain voltage Vds decreases as the drain current Id decreases, and finally converges. The drain current Id also finally converges. As the period from time t43 to time t44 is longer, the surge becomes smaller.

As illustrated in FIGS. 3 and 5, the waveform of the driving voltage Vdv in the period from time t21 to time t24 in FIG. 3 is a waveform obtained by inverting the waveform of the driving voltage Vdv in the period from time t41 to time 44 in FIG. 5.

Hereinafter, the voltage supplied to the gate of the switch element 41 for turning on or turning off is referred to as a “first driving voltage V1”. A period during which the first driving voltage V1 is supplied is referred to as a “first driving period T1”. The voltage supplied to the gate of the switch element 41 to suppress generation of a large surge is referred to as a “brake voltage Vb”. A period during which the brake voltage Vb is supplied is referred to as a “brake period Tb”. After the brake period Tb has elapsed, the voltage supplied to the gate of the switch element 41 to suppress the increase in conduction loss or switching loss is referred to as a “second driving voltage V2”.

In a case where the switch element 41 is turned on, the first driving voltage V1 is the voltage Vdv2 as illustrated in FIG. 3. The first driving period T1 is a period from time t21 to time t23. The brake voltage Vb is the voltage Vdv3. The brake period Tb is a period from time t23 to time t24. The second driving voltage V2 is the voltage Vdv2.

In a case where the switch element 41 is turned off, the first driving voltage V1 is the voltage Vdv5 as illustrated in FIG. 5. The first driving period T1 is a period from time t41 to time t43. The brake voltage Vb is the voltage Vdv6. The brake period Tb is a period from time t43 to time t44. The second driving voltage V2 is the voltage Vdv5.

The second driving voltage V2 may not be the same as the first driving voltage V1. That is, the second driving voltage V2 may be a voltage higher than the first driving voltage V1 or a voltage lower than the first driving voltage V1.

As described above, in the active gate control, the first driving voltage V1, the first driving period T1, the brake voltage Vb, the brake period Tb, and the second driving voltage V2 are set.

The first driving voltage V1, the first driving period T1, the brake voltage Vb, the brake period Tb, and the second driving voltage V2 are determined according to the drain current Id, the drain voltage Vds, and the temperature Temp of the switch element 41.

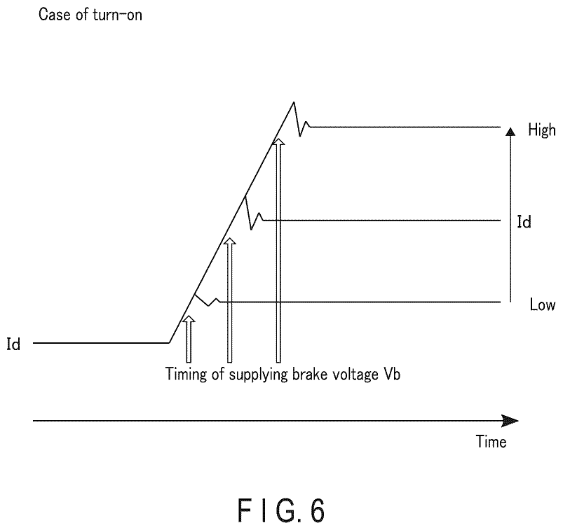

FIG. 6 is a diagram illustrating an example of the supply timing of the brake voltage Vb according to the drain current Id in a case where the switch element 41 is turned on by the active gate control of the semiconductor device 1. FIG. 6 illustrates an example of a waveform of the drain current Id in a case where the switch element 41 is turned on by the normal gate control in the semiconductor device of the comparative example. The three waveforms illustrated in FIG. 6 correspond to a case where the drain current Id is low, a case where the drain current Id is high, and a case where the drain current Id takes a value between the two, respectively.

As illustrated in FIG. 6, the higher the drain current Id, the later the timing at which the surge of the drain current Id occurs. In addition, the surge of the drain current Id is larger as the drain current Id is higher. Therefore, in a case where the switch element 41 is turned on by the active gate control of the semiconductor device 1, it is preferable that the brake voltage Vb is supplied before the surge occurs according to the value of the drain current Id as indicated by the arrows in FIG. 6. For example, the timing of supplying the brake voltage Vb is delayed as the drain current Id is higher.

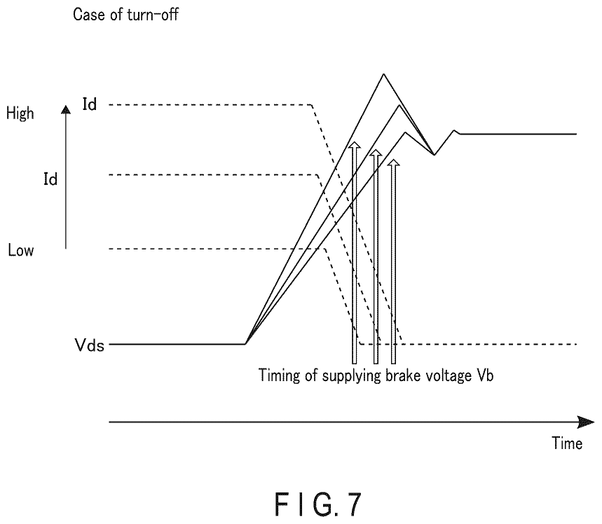

FIG. 7 is a diagram illustrating an example of the supply timing of the brake voltage Vb according to the drain current Id in a case where the switch element 41 is turned off by the active gate control of the semiconductor device 1. FIG. 7 illustrates an example of waveforms of the drain current Id and the drain voltage Vds in a case where the switch element 41 is turned off by the normal gate control in the semiconductor device of the comparative example. The drain current Id is indicated by the broken line, and the drain voltage Vds is indicated by the solid line. The three waveforms of the broken lines illustrated in FIG. 7 correspond to a case where the drain current Id is low, a case where the drain current Id is high, and a case where the drain current Id takes a value between the two, respectively. Among the three waveforms of the solid lines illustrated in FIG. 7, the waveform with the smallest surge of the drain voltage Vds corresponds to the case where the drain current Id is low, and the waveform with the largest surge of the drain voltage Vds corresponds to the case where the drain current Id is high. The remaining waveform corresponds to the case where the drain current Id takes a value between the case of low current and the case of high current.

As illustrated in FIG. 7, the higher the drain current Id, the earlier the timing at which the surge of the drain voltage Vds occurs. In addition, the surge of the drain voltage Vds is larger as the drain current Id is higher. Therefore, in a case where the switch element 41 is turned off by the active gate control of the semiconductor device 1, it is preferable that the brake voltage Vb is supplied before the surge of the drain voltage Vds occurs according to the value of the drain current Id as indicated by the arrows in FIG. 7. For example, the timing of supplying the brake voltage Vb is advanced as the drain current Id is higher.

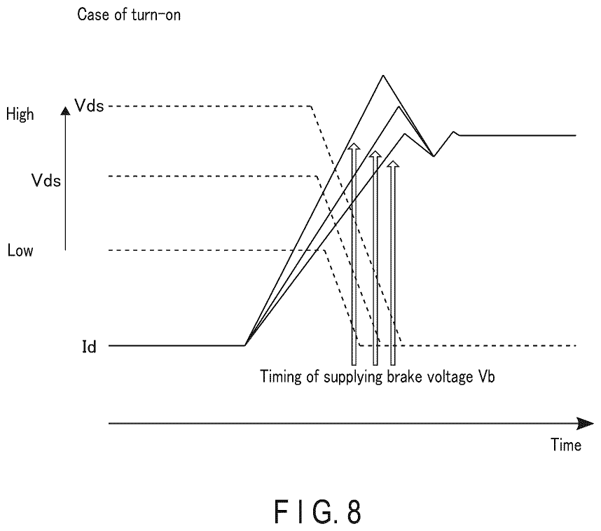

FIG. 8 is a diagram illustrating an example of the supply timing of the brake voltage Vb according to the drain voltage Vds in a case where the switch element 41 is turned on by the active gate control of the semiconductor device 1. FIG. 8 illustrates an example of waveforms of the drain current Id and the drain voltage Vds in a case where the switch element 41 is turned on by the normal gate control in the semiconductor device of the comparative example. The drain current Id is indicated by the solid line, and the drain voltage Vds is indicated by the broken line. The waveforms of the three broken lines illustrated in FIG. 8 correspond to a case where the drain voltage Vds is low, a case where the drain voltage Vds is high, and a case where the drain voltage Vds takes a value between the two, respectively. Among the waveforms of the three solid lines illustrated in FIG. 8, the waveform with the smallest surge of the drain current Id corresponds to the case where the drain voltage Vds is low, and the waveform with the largest surge of the drain current Id corresponds to the case where the drain voltage Vds is high. The remaining waveform corresponds to the case where the drain voltage Vds takes a value between the case of low current and the case of high current.

As illustrated in FIG. 8, the higher the drain voltage Vds, the earlier the timing at which the surge of the drain current Id occurs. In addition, the surge of the drain current Id is larger as the drain voltage Vds is higher. Therefore, in the active gate control by the semiconductor device 1, it is preferable that the brake voltage Vb is applied before the surge of the drain current Id occurs according to the value of the drain voltage Vds as indicated by the arrows in FIG. 8. For example, the timing of supplying the brake voltage Vb is advanced as the drain voltage Vds is higher.

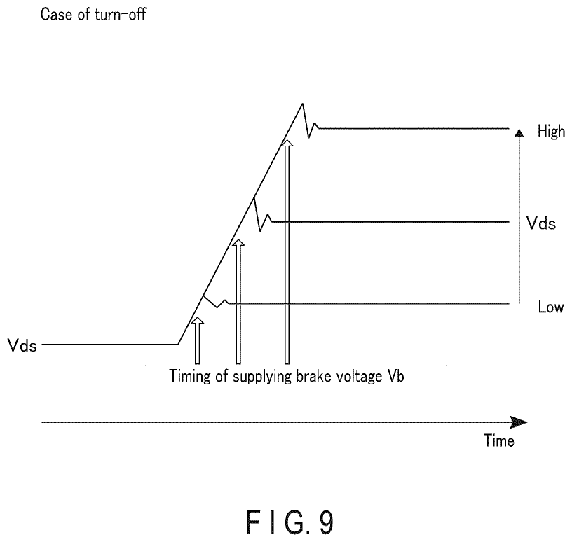

FIG. 9 is a diagram illustrating an example of the supply timing of the brake voltage Vb according to the drain voltage Vds in a case where the switch element 41 is turned off by the active gate control of the semiconductor device 1. FIG. 9 illustrates an example of the waveform of the drain voltage Vds in a case where the switch element 41 is turned off by the normal gate control in the semiconductor device of the comparative example. The three waveforms illustrated in FIG. 9 correspond to a case where the drain voltage Vds is low, a case where the drain voltage Vds is high, and a case where the drain voltage Vds takes a value between the two, respectively.

As illustrated in FIG. 9, the higher the drain voltage Vds, the later the timing at which the surge of the drain voltage Vds occurs. In addition, the surge of the drain voltage Vds is larger as the drain voltage Vds is higher. Therefore, in a case where the switch element 41 is turned off by the active gate control of the semiconductor device 1, it is preferable that the brake voltage Vb is supplied before the surge occurs according to the value of the drain voltage Vds as indicated by the arrows in FIG. 9. For example, the timing of supplying the brake voltage Vb is delayed as the drain voltage Vds is higher.

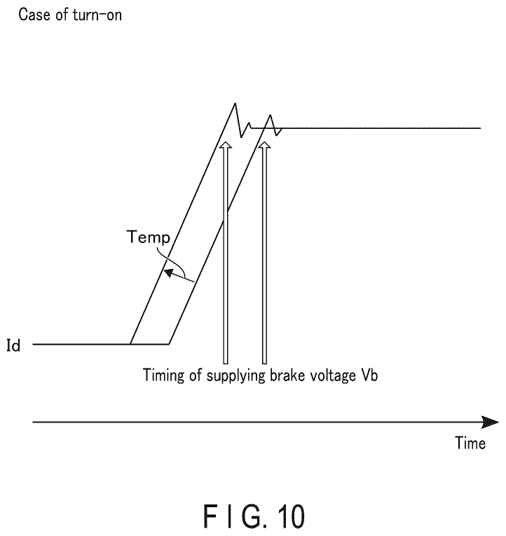

FIG. 10 is a diagram illustrating an example of the supply timing of the brake voltage Vb according to the temperature Temp in a case where the switch element 41 is turned on by the active gate control of the semiconductor device 1. FIG. 10 illustrates an example of waveforms of the drain current Id in a case where the switch element 41 is turned on by the normal gate control in the semiconductor device of the comparative example. Among the two waveforms illustrated in FIG. 10, the waveform with a smaller surge of the drain current Id corresponds to a case where the temperature Temp is low, and the waveform with a larger surge of the drain current Id corresponds to a case where the temperature Temp is high.

As illustrated in FIG. 10, the higher the temperature Temp, the earlier the timing at which the surge of the drain current Id occurs. In addition, the surge of the drain current Id is larger as the temperature Temp is higher. Therefore, in the active gate control by the semiconductor device 1, it is preferable that the brake voltage Vb is supplied before the surge of the drain current Id occurs according to the value of the temperature Temp as indicated by the arrows in FIG. 10. For example, the timing of supplying the brake voltage Vb is advanced as the temperature Temp is higher.

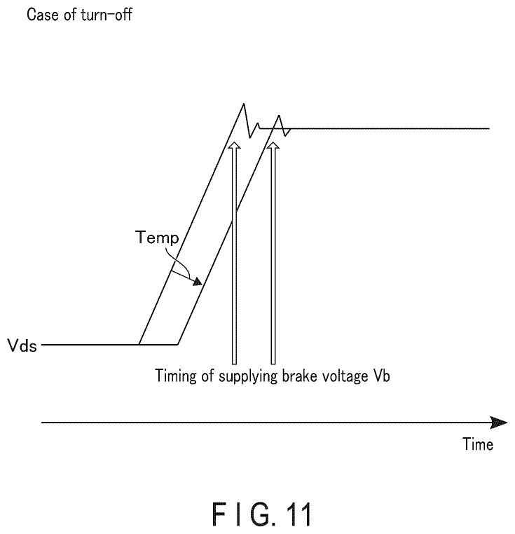

FIG. 11 is a diagram illustrating an example of the supply timing of the brake voltage Vb according to the temperature Temp in a case where the switch element 41 is turned off by the active gate control of the semiconductor device 1. FIG. 11 illustrates an example of waveforms of the drain voltage Vds in a case where the switch element 41 is turned off by the normal gate control in the semiconductor device of the comparative example. Among the two waveforms illustrated in FIG. 11, the waveform with a smaller surge of the drain voltage Vds corresponds to a case where the temperature Temp is high, and the waveform with a larger surge of the drain voltage Vds corresponds to a case where the temperature Temp is low.

As illustrated in FIG. 11, the higher the temperature Temp, the later the timing at which the surge of the drain voltage Vds occurs. In addition, the surge of the drain voltage Vds is smaller as the temperature Temp is higher. Therefore, in a case where the switch element 41 is turned off by the active gate control of the semiconductor device 1, it is preferable that the brake voltage Vb is supplied before the surge of the drain voltage Vds occurs according to the value of the temperature Temp as indicated by the arrows in FIG. 11. For example, the timing of supplying the brake voltage Vb is delayed as the temperature Temp is higher.

From the above, driving patterns Pa according to the changes in the environment in which the switch element 41 is placed, that is, the changes in the system information INF (the changes in the drain current Id, the drain voltage Vds, and the temperature Temp) are prepared in the active gate control of the semiconductor device 1. Each of the driving patterns Pa is based on a combination of the drain current Id, the drain voltage Vds, and the temperature Temp. The driving pattern Pa includes a parameter PM1 corresponding to the first driving voltage V1, a parameter PM2 corresponding to the first driving period T1, a parameter PM3 corresponding to the brake voltage Vb, a parameter PM4 corresponding to the brake period Tb, and a parameter PM5 corresponding to the second driving voltage V2. The parameters PM1 to PM5 are determined according to the drain current Id, the drain voltage Vds, and the temperature Temp. In other words, the parameters PM1 to PM5 are appropriate parameters according to the drain current Id, the drain voltage Vds, and the temperature Temp. In the present embodiment, the lookup table LUT is used as information for storing the driving patterns Pa in order to switch the driving patterns Pa suitable for the active gate control following the environmental changes.

### Lookup Table

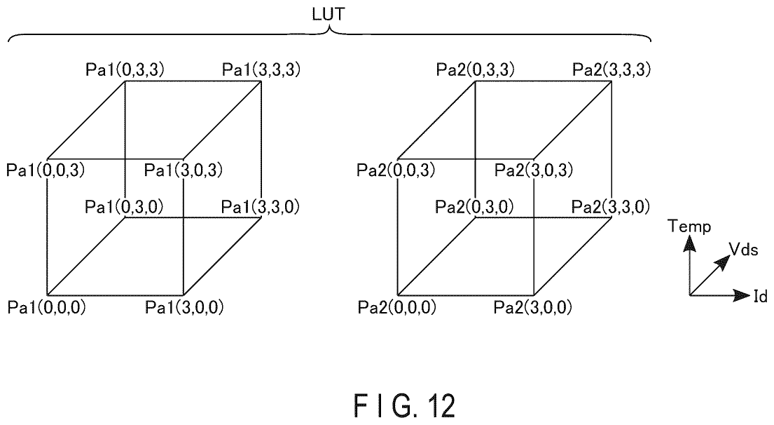

FIG. 12 is a conceptual diagram illustrating an example of the lookup table LUT used in the semiconductor device 1 according to the present embodiment. In the present embodiment, as the driving patterns Pa for a case where the switch element 41 is turned on, 64 driving patterns Pa1, which are the number of combinations of four drain currents Id, four drain voltages Vds, and four temperatures Temp, are prepared. In addition, as the driving patterns Pa for a case where the switch element 41 is turned off, 64 driving patterns Pa2, which are the number of combinations of four drain currents Id, four drain voltages Vds, and four temperatures Temp, are prepared. That is, the lookup table LUT includes 64 driving patterns Pa1 and 64 driving patterns Pa2.

Hereinafter, the 64 driving patterns Pa1 are referred to as “Driving pattern Pa1(i, j, k)”, and the 64 driving patterns Pa2 are referred to as “Driving pattern Pa2(i, j, k)” (i, j, and k are integers that are 0 or more and three or less.). In a case where Driving patterns Pa1(i, j, k) and Pa2(i, j, k) are not distinguished, they are referred to as “Driving pattern Pa(i, j, k)”.

The letter i corresponds to the drain current Id, and indicates the driving pattern Pa in a case where the drain current Id is higher as the value of i is larger. The drain current Id corresponding to Driving pattern Pa(i+1, j, k) is higher than the drain current Id corresponding to Driving pattern Pa(i, j, k). The drain current Id corresponding to Driving pattern Pa(i−1, j, k) is lower than the drain current Id corresponding to Driving pattern Pa(i, j, k).

The letter j corresponds to the drain voltage Vds, and indicates the driving pattern Pa in a case where the drain voltage Vds is higher as the value of j is larger. The drain voltage Vds corresponding to Driving pattern Pa(i, j+1, k) is higher than the drain voltage Vds corresponding to Driving pattern Pa(i, j, k). The drain voltage Vds corresponding to Driving pattern Pa(i, j−1, k) is lower than the drain voltage Vds corresponding to Driving pattern Pa(i, j, k).

The letter k corresponds to the temperature Temp, and indicates the driving pattern Pa in a case where the temperature Temp is higher as the value of k is larger. The temperature Temp corresponding to Driving pattern Pa(i, j, k+1) is higher than the temperature Temp corresponding to Driving pattern Pa(i, j, k). The temperature Temp corresponding to Driving pattern Pa(i, j, k−1) is lower than the temperature Temp corresponding to Driving pattern Pa(i, j, k).

The number of each of the drain current Id, the drain voltage Vds, and the temperature Temp used for each of Driving patterns Pa1(i, j, k) and Pa2(i, j, k) may not be four, may be three or less, or may be five or more. Each of Driving patterns Pa1(i, j, k) and Pa2(i, j, k) includes the above-described five parameters PM1 to PM5.

The drain current Id changes according to the rotation of the motor. The rotation of the motor changes frequently. Therefore, the drain current Id changes fast. On the other hand, the drain voltage Vds and the temperature Temp change slowly. The drain current Id, the drain voltage Vds, and the temperature Temp have such change characteristics. The timing of supplying the brake voltage Vb can be predicted from the changes in the drain current Id, the drain voltage Vds, and the temperature Temp.

From the above, 64 driving patterns Pa1 and 64 driving patterns Pa2 are prepared based on the above-described characteristics of the changes in the drain current Id, the drain voltage Vds, and the temperature Temp.

For example, immediately after the semiconductor device 1 is powered on, the lookup table LUT is loaded from the ROM in the memory 22 to the RAM in the MCU 2.

In a case where the switch element 41 is turned on or off and the driving pattern Pa is loaded from the RAM in the memory 22 to the RAM in the memory 32 each time, communication between the MCU 2 and the gate driver 3 takes time, and active gate control may not be supported.

In addition, in a case where more driving patterns Pa are loaded in advance, before the switch element 41 is turned on or off, from the RAM in the memory 22 to the RAM in the memory 32 so as to be able to cope with expected various changes in the system information INF, the capacity of the memory 32 increases, leading to an increase in cost. In this case, the occupied area of the gate driver 3 increases, and the gate driver 3 may not fit in the semiconductor device 1.

Hereinafter, the driving pattern Pa corresponding to the current system information INF is referred to as “Current pattern Pac(ic, jc, kc)”. The current pattern Pac is a driving pattern Pa predicted from the current system information INF. In a case where the switch element 41 is turned on or off, none of the drain current Id, the drain voltage Vds, and the temperature Temp changes rapidly. Therefore, for example, in a case where the switch element 41 is turned on or off and the drain current Id changes, the driving pattern Pa is changed from the current pattern Pac to a driving pattern Pa in which the value of i is increased or decreased by one. That is, the driving pattern Pa is changed to Driving pattern Pa(ic+1, jc, kc) or Driving pattern Pa(ic−1, jc, kc). In a case where the switch element 41 is turned on or off and the drain voltage Vds changes, the driving pattern Pa is changed from the current pattern Pac to a driving pattern Pa in which the value of j is increased or decreased by one. That is, the driving pattern Pa is changed to Driving pattern Pa(ic, jc+1, kc) or Driving pattern Pa(ic, jc−1, kc). In a case where the switch element 41 is turned on or off and the temperature Temp changes, the driving pattern Pa is changed from the current pattern Pac to a driving pattern Pa in which the value of k is increased or decreased by one. That is, the driving pattern Pa is changed to Driving pattern Pa(ic, jc, kc+1) or Driving pattern Pa(ic, jc, kc−1).

Furthermore, in a case where the change in the system information INF is small, the appropriate driving pattern Pa becomes a pattern similar to the current pattern Pac. Therefore, even if the current pattern Pac is not switched, appropriate active gate control can be performed according to the changes in the system information INF by changing the brake voltage Vb supply timing based on the current pattern Pac. On the other hand, in a case where the change in the system information INF is large, the appropriate driving pattern Pa becomes a pattern not similar to the current pattern Pac. Therefore, unless the current pattern Pac is switched, there is a possibility that appropriate active gate control according to a change in the system information INF cannot be performed.

From the above, in the present embodiment, among all the driving patterns Pa included in the lookup table LUT, Current pattern Pac(ic, jc, kc), Driving pattern Pa(ic±1, jc, kc), Driving pattern Pa(ic, jc±1, kc), and Driving pattern Pa(ic, jc, kc±1) are loaded from the memory 22 to the memory 32. The current pattern Pac is a driving pattern expected to be changed at the timing when the switch element 41 is turned on or off based on the system information INF by the MCU 2. Hereinafter, Driving pattern Pa(ic±1, jc, kc), Driving pattern Pa(ic, jc±1, kc), and Driving pattern Pa(ic, jc, kc±1) are also referred to as “six driving patterns Pa adjacent to the current pattern Pac”. Driving pattern Pa(ic±1, jc, kc) is a driving pattern that corresponds to a case where the drain current Id increases or decreases from the current pattern Pac. Driving pattern Pa(ic, jc±1, kc) is a driving pattern that corresponds to a case where the drain voltage Vds increases or decreases from the current pattern Pac. Driving pattern Pa(ic, jc, kc±1) is a driving pattern that corresponds to a case where the temperature Temp increases or decreases from the current pattern Pac. The lookup table LUT including the seven driving patterns Pa loaded into the memory 32 is referred to as a “lookup table LUTg”. That is, the lookup table LUTg is stored in the memory 32.

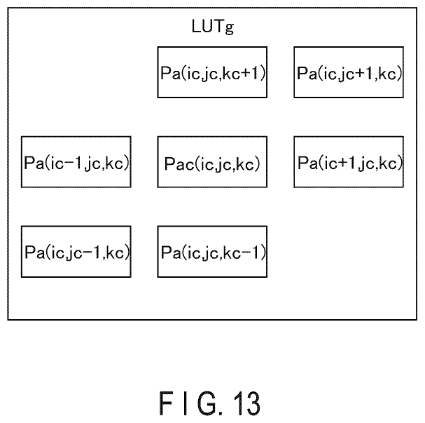

FIG. 13 is a conceptual diagram illustrating an example of the lookup table LUTg stored in the memory 32. As illustrated in FIG. 13, the lookup table LUTg includes Current pattern Pac(ic, jc, kc), Driving pattern Pa(ic±1, jc, kc), Driving pattern Pa(ic, jc±1, kc), and Driving pattern Pa(ic, jc, kc±1). The loading of these driving patterns Pa into the memory 32 is performed, for example, immediately after the semiconductor device 1 is powered on and after the switch element 41 is turned on or off.

### 1.1.3 Functional Configuration of Control Circuit

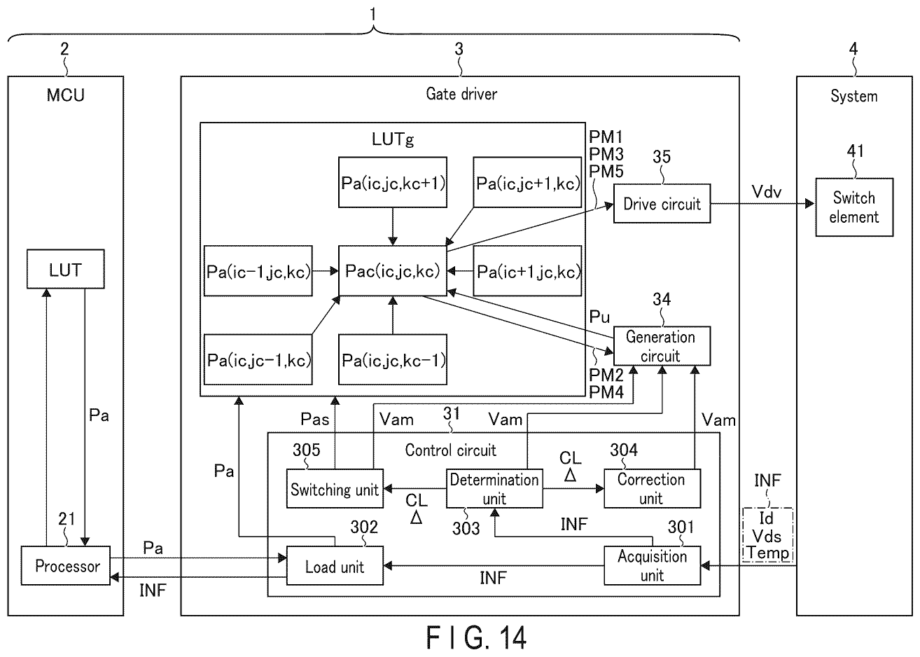

A functional configuration of the control circuit 31 in the gate driver 3 will be described with reference to FIG. 14. FIG. 14 is a block diagram illustrating an example of the functional configuration of the control circuit 31. FIG. 14 also illustrates the MCU 2, the system 4, and the lookup table LUTg, the generation circuit 34, and the drive circuit 35 in the gate driver 3.

As illustrated in FIG. 14, the control circuit 31 includes an acquisition unit 301, a load unit 302, a determination unit 303, a correction unit 304, and a switching unit 305 as functional blocks. That is, the control circuit 31 functions as the acquisition unit 301, the load unit 302, the determination unit 303, the correction unit 304, and the switching unit 305.

### Acquisition Unit 301

The acquisition unit 301 executes the system information acquisition process. For example, the acquisition unit 301 acquires the system information INF (the value of drain current Id, the value of drain voltage Vds, and the value of temperature Temp) from the system 4.

### Load Unit 302

The load unit 302 executes the driving pattern load process. For example, the load unit 302 receives the system information INF from the acquisition unit 301. The load unit 302 transmits the received system information INF to the processor 21 in the MCU 2. In a case where the processor 21 receives the system information INF, the processor 21 acquires the current pattern Pac corresponding to the system information INF (current system information INF) and the six driving patterns Pa adjacent to the current pattern Pac from the lookup table LUT. For example, immediately after the semiconductor device 1 is turned on and after the switch element 41 is turned off (after the semiconductor device 1 enters the steady state), the seven driving patterns are acquired from the 64 driving patterns Pa1 in the lookup table LUT, and after the switch element 41 is turned on (after the semiconductor device 1 enters the steady state), the seven driving patterns are acquired from the 64 driving patterns Pa2 in the lookup table LUT. The processor 21 transmits the acquired driving patterns Pa to the load unit 302. Upon receiving the driving pattern Pa, the load unit 302 updates the driving patterns Pa in the lookup table LUTg.

### Determination Unit 303

The determination unit 303 executes the system information determination process. For example, the determination unit 303 receives the system information INF from the acquisition unit 301. The determination unit 303 determines whether there is a change in the system information INF. In a case where there is no change in the system information INF, a value (=0) indicating that the supply timing is not corrected is transmitted to the generation circuit 34 as a correction value Vam of the brake voltage Vb supply timing. In a case where a change in the system information INF is small, a type (drain current Id, drain voltage Vds, or temperature Temp) CL of the changed information and a change amount Δ are transmitted to the correction unit 304. In a case where a change in the system information INF is large, the type CL of the changed information and the change amount Δ are transmitted to the switching unit 305.

### Correction Unit 304

The correction unit 304 executes the driving pattern correction process. For example, in a case where the type CL and the change amount Δ are received from the determination unit 303, the correction unit 304 generates a correction value Vam of the brake voltage Vb supply timing. The correction unit 304 transmits the generated correction value Vam to the generation circuit 34.

For example, in a case where the switch element 41 is turned on and the drain current Id rises (change amount ΔId>0), the timing of the surge of the drain current Id becomes later as illustrated in FIG. 6. Therefore, in a case where the drain current Id rises, the correction unit 304 generates a positive correction value Vam in order to delay the brake voltage Vb supply timing. In a case where the switch element 41 is turned on and the drain current Id decreases (change amount ΔId<0), the timing of the surge of the drain current Id becomes earlier as illustrated in FIG. 6. Therefore, in a case where the drain current Id decreases, the correction unit 304 generates a negative correction value Vam in order to make the brake voltage Vb supply timing earlier. On the other hand, in a case where the switch element 41 is turned off and the drain current Id rises, the timing of the surge of the drain voltage Vds becomes earlier as illustrated in FIG. 7. Therefore, in a case where the drain current Id increases, the correction unit 304 generates a negative correction value Vam in order to make the brake voltage Vb supply timing earlier. In a case where the switch element 41 is turned off and the drain current Id decreases, the timing of the surge of the drain voltage Vds becomes later as illustrated in FIG. 7. Therefore, in a case where the drain current Id decreases, the correction unit 304 generates a positive correction value Vam in order to delay the brake voltage Vb supply timing. The correction value Vam is generated based on the change amount ΔId.

In a case where the switch element 41 is turned on and the drain voltage Vds rises (change amount ΔVds>0), the timing of the surge of the drain current Id becomes earlier as illustrated in FIG. 8. Therefore, in a case where the drain voltage Vds rises, the correction unit 304 generates a negative correction value Vam in order to make the brake voltage Vb supply timing earlier. In a case where the switch element 41 is turned on and the drain voltage Vds decreases (change amount ΔVds<0), the timing of the surge of the drain current Id becomes later as illustrated in FIG. 8. Therefore, in a case where the drain voltage Vds decreases, the correction unit 304 generates a positive correction value Vam in order to delay the brake voltage Vb supply timing. On the other hand, in a case where the switch element 41 is turned off and the drain voltage Vds rises, the timing of the surge of the drain voltage Vds becomes later as illustrated in FIG. 9. Therefore, in a case where the drain voltage Vds rises, the correction unit 304 generates a positive correction value Vam in order to delay the brake voltage Vb supply timing. In a case where the switch element 41 is turned off and the drain voltage Vds decreases, the timing of the surge of the drain voltage Vds becomes earlier as illustrated in FIG. 9. Therefore, in a case where the drain voltage Vds decreases, the correction unit 304 generates a negative correction value Vam in order to make the brake voltage Vb supply timing earlier. The correction value Vam is generated based on the change amount ΔVds.

In a case where the switch element 41 is turned on and the temperature Temp rises (change amount ΔTemp>0), the timing of the surge of the drain current Id becomes earlier as illustrated in FIG. 10. Therefore, in a case where the temperature Temp rises, the correction unit 304 generates a negative correction value Vam in order to make the brake voltage Vb supply timing earlier. In a case where the switch element 41 is turned on and the temperature Temp drops (change amount ΔTemp<0), the timing of the surge of the drain current Id becomes later as illustrated in FIG. 10. Therefore, in a case where the temperature Temp drops, the correction unit 304 generates a positive correction value Vam in order to delay the brake voltage Vb supply timing. On the other hand, in a case where the switch element 41 is turned off and the temperature Temp rises, the timing of the surge of the drain voltage Vds becomes later as illustrated in FIG. 11. Therefore, in a case where the temperature Temp rises, the correction unit 304 generates a positive correction value Vam in order to delay the brake voltage Vb supply timing. In a case where the switch element 41 is turned off and the temperature Temp drops, the timing of the surge of the drain voltage Vds becomes earlier as illustrated in FIG. 11. Therefore, in a case where the temperature Temp drops, the correction unit 304 generates a negative correction value Vam in order to make the brake voltage Vb supply timing earlier. The correction value Vam is generated based on the change amount ΔTemp.

### Switching Unit 305

The switching unit 305 executes the driving pattern switching process. For example, upon receiving the type CL and the change amount Δ from the determination unit 303, the switching unit 305 determines one driving pattern Pa (hereinafter, referred to as a “switching pattern Pas”) to be switched to the current pattern Pac among the six driving patterns Pa adjacent to the current pattern Pac. The switching unit 305 transmits the determined switching pattern Pas to the lookup table LUTg and switches the current pattern Pac in the lookup table LUTg to the switching pattern Pas. That is, the current pattern Pac is replaced with the switching pattern Pas. Hereinafter, the current pattern Pac after the replacement is also referred to as a “replaced current pattern Pacr”. As a result, the current pattern Pac and the five driving patterns Pa adjacent to the current pattern Pac are stored in the memory 32.

For example, in a case where the switch element 41 is turned on or off and the drain current Id rises (change amount ΔId>0), the switching unit 305 determines Driving pattern Pa(ic+1, jc, kc) as the switching pattern Pas. The current pattern Pac is switched from Driving pattern Pa(ic, jc, kc) to Driving pattern Pa(ic+1, jc, kc). In a case where the switch element 41 is turned on or off and the drain current Id decreases (change amount ΔId<0), the switching unit 305 determines Driving pattern Pa(ic−1, jc, kc) as the switching pattern Pas. The current pattern Pac is switched from Driving pattern Pa(ic, jc, kc) to Driving pattern Pa(ic−1, jc, kc).

In a case where the switch element 41 is turned on or off and the drain voltage Vds increases (change amount ΔVds>0), the switching unit 305 determines Driving pattern Pa(ic, jc+1, kc) as the switching pattern Pas. The current pattern Pac is switched from Driving pattern Pa(ic, jc, kc) to Driving pattern Pa(ic, jc+1, kc). In a case where the switch element 41 is turned on or off and the drain voltage Vds decreases (change amount ΔVds<0), the switching unit 305 determines Driving pattern Pa(ic, jc−1, kc) as the switching pattern Pas. The current pattern Pac is switched from Driving pattern Pa(ic, jc, kc) to Driving pattern Pa(ic, jc−1, kc).

In a case where the switch element 41 is turned on or off and the temperature Temp rises (change amount ΔTemp>0), the switching unit 305 determines Driving pattern Pa(ic, jc, kc+1) as the switching pattern Pas. The current pattern Pac is switched from Driving pattern Pa(ic, jc, kc) to Driving pattern Pa(ic, jc, kc+1). In a case where the switch element 41 is turned on or off and the temperature Temp drops (change amount ΔTemp<0), the switching unit 305 determines Driving pattern Pa(ic, jc, kc−1) as the switching pattern Pas. The current pattern Pac is switched from Driving pattern Pa(ic, jc, kc) to Driving pattern Pa(ic, jc, kc−1).

In addition, the switching unit 305 transmits a value (=0) indicating that the supply timing is not corrected to the generation circuit 34 as the correction value Vam of the brake voltage Vb supply timing.

The generation circuit 34 acquires the parameter PM2 corresponding to the first driving period T1 of the current pattern Pac and the parameter PM4 corresponding to the brake period Tb from the lookup table LUTg. In addition, the generation circuit 34 receives the correction value Vam from the determination unit 303, the correction unit 304, or the switching unit 305. The generation circuit 34 generates the driving pulse Pu based on the parameters PM2 and PM4 of the current pattern Pac and the correction value Vam. For example, in a case where the correction value Vam (=0) is received from the determination unit 303, the generation circuit 34 generates the driving pulse Pu based on the parameters PM2 and PM4 of the current pattern Pac. In a case where the correction value Vam (≠0) is received from the correction unit 304, the generation circuit 34 generates the driving pulse Pu based on the parameters PM2 and PM4 of the current pattern Pac and the correction value Vam. The correction value Vam is added to the parameter PM2 corresponding to the first driving period T1. In a case where the correction value Vam (=0) is received from the switching unit 305, the generation circuit 34 generates the driving pulse Pu based on the parameters PM2 and PM4 of the replaced current pattern Pacr. The generation circuit 34 transmits the generated driving pulse Pu to the current pattern Pac in the lookup table LUTg.

At the timing based on the driving pulse Pu, the parameter PM1 corresponding to the first driving voltage V1, the parameter PM3 corresponding to the brake voltage Vb, and the parameter PM5 corresponding to the second driving voltage V2 are transmitted from the current pattern Pac in the lookup table LUTg to the drive circuit 35. The parameters PM1, PM3, and PM5 are stored in a register (not illustrated) in the drive circuit 35, converted into voltages, and then supplied to the switch element 41 as the driving voltage Vdv.

### 1.1.4 Configuration of Lookup Table LUTg

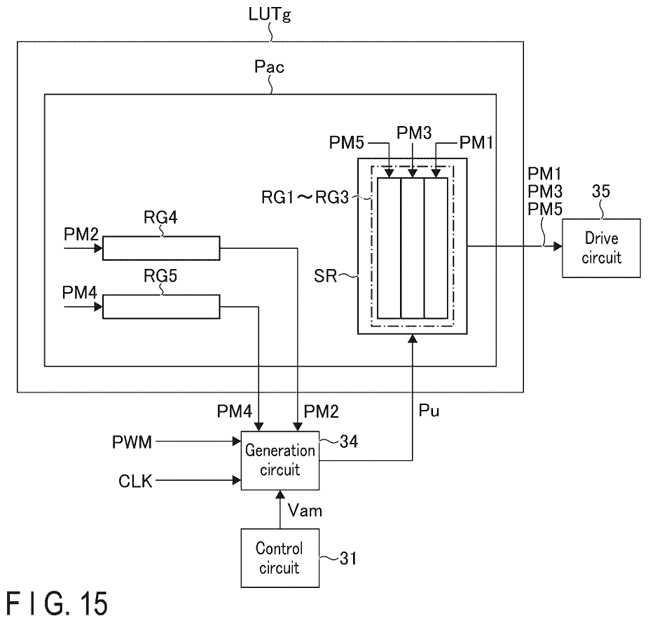

The configuration of the lookup table LUTg will be described with reference to FIG. 15. FIG. 15 is a diagram illustrating an example of a configuration of the lookup table LUTg. FIG. 15 illustrates only the current pattern Pac among the seven driving patterns Pa in the lookup table LUTg. The other driving patterns Pa in the lookup table LUTg also have the same configuration as the current pattern Pac. FIG. 15 also illustrates the control circuit 31, the generation circuit 34, and the drive circuit 35.

As illustrated in FIG. 15, the current pattern Pac includes registers RG1 to RG5.

The registers RG1 to RG3 are registers RG1, RG2, and RG3 in this order from the right side of the drawing. The parameter PM1 corresponding to the first driving voltage V1 is stored in the register RG1. The parameter PM3 corresponding to the brake voltage Vb is stored in the register RG2. The parameter PM5 corresponding to the second driving voltage V2 is stored in the register RG3. The parameters PM1, PM3, and PM5 are values indicating the driving force. The driving force takes a value from 0 to 63, for example. In a case where the driving force takes a value from 0 to 63, each of the registers RG1 to RG3 includes, for example, six flip-flops. As an example of the driving force set to each of the registers RG1 to RG3, for example, “60” is set to the register RG1, “4” is set to the register RG2, and “60” is set to the register RG3. The registers RG1 to RG3 constitute a shift register SR.

The parameter PM2 corresponding to the first driving period T1 is stored in the register RG4. The parameter PM4 corresponding to the brake period Tb is stored in the register RG5. The parameters PM2 and PM4 are values indicating a voltage supply period. The voltage supply period takes a value from 0 to 31, for example. In a case where the voltage supply period takes a value from 0 to 31, each of the registers RG4 and RG5 includes, for example, five flip-flops. As an example of the voltage supply period set in each of the registers RG4 and RG5, for example, “6” is set in the register RG4 and “4” is set in the register RG5.

The generation circuit 34 receives the signals CLK and PWM from the MCU 2. The generation circuit 34 acquires the parameters PM2 and PM4 from the current pattern Pac. The generation circuit 34 receives the correction value Vam from the control circuit 31. The generation circuit 34 generates the driving pulse Pu based on the signals CLK and PWM, the parameters PM2 and PM4, and the correction value Vam. The generation circuit 34 transmits the generated driving pulse Pu to the shift register SR of the current pattern Pac.

The shift register SR shifts the values stored in the registers RG1 to RG3 at the rising timing of the driving pulse Pu, and the parameter PM is output from the register RG1 to the drive circuit 35. First, the parameter PM1 is output from the register RG1 to the drive circuit 35. Next, the parameter PM3 is output from the register RG1 to the drive circuit 35. Next, the parameter PM5 is output from the register RG1 to the drive circuit 35.

### 1.1.5 Configuration of Generation Circuit

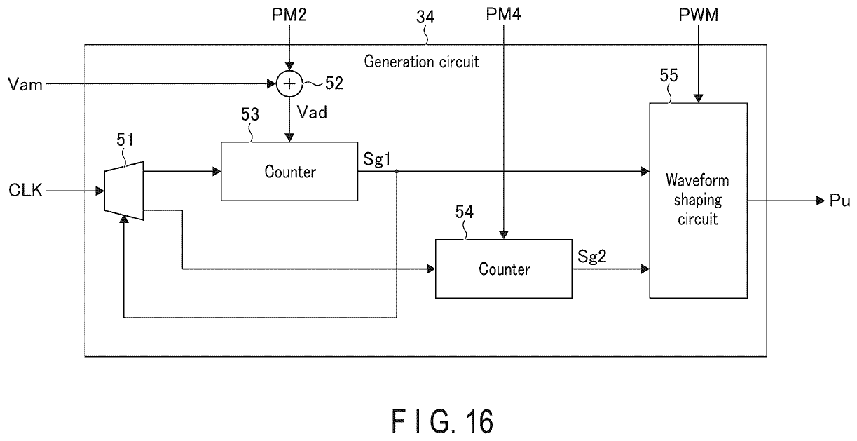

The configuration of the generation circuit 34 will be described with reference to FIG. 16. FIG. 16 is a circuit diagram showing an example of a configuration of the generation circuit 34.

As illustrated in FIG. 16, the generation circuit 34 includes a multiplexer (MUX) 51, an adder 52, counters 53 and 54, and a waveform shaping circuit 55.

The MUX 51 is a circuit that selects one of the counters 53 and 54 based on a signal Sg1 output from the counter 53 and outputs the input signal CLK to the selected counter.

The adder 52 is a circuit that adds the correction value Vam to the parameter PM2 and outputs a result of the addition to the counter 53 as an addition value Vad. Since the correction value Vam is any of a negative value, zero, and a positive value, the addition value Vad is any of a value smaller than the value of the parameter PM2, a value equal to the value of the parameter PM2, and a value larger than the value of the parameter PM2.

The counter 53 is a circuit that receives the signal CLK from the MUX 51 and determines whether or not the count value Cnt of the signal CLK has reached the addition value Vad received from the adder 52. In a case where the count value Cnt has not reached the addition value Vad, the counter 53 outputs a first value (for example, “0”) as the signal Sg1. In a case where the count value Cnt reaches the addition value Vad, the counter 53 outputs a second value (for example, “1”) as the signal Sg1.

The counter 54 is a circuit that receives the signal CLK from the MUX 51 and determines whether or not the count value Cnt of the signal CLK has reached the value of the parameter PM4. The counter 54 does not output a signal Sg2 in a case where the count value Cnt does not reach the value of the parameter PM4. The counter 54 outputs a signal Sg2 in a case where the count value Cnt reaches the value of the parameter PM4.

The waveform shaping circuit 55 is a circuit that generates the driving pulse Pu based on the signal PWM, Sg1, or Sg2, and shapes and outputs the waveform of the generated driving pulse Pu. The waveform shaping circuit 55 generates and outputs the driving pulse Pu at the rising or falling timing of the signal PWM. In a case where the signal Sg1 indicating the second value is received, the waveform shaping circuit 55 generates and outputs the driving pulse Pu. In a case where the signal Sg2 is received, the waveform shaping circuit 55 generates and outputs the driving pulse Pu.

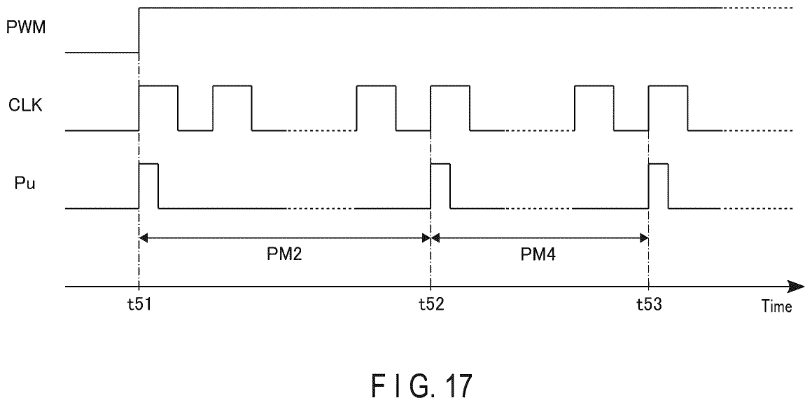

FIG. 17 is a diagram showing an example of a waveform of the driving pulse Pu generated by the generation circuit 34. FIG. 17 illustrates a waveform in a case where switch element 41 is turned on.

At time t51, the signals PWM and CLK rise. As a result, the waveform shaping circuit 55 generates and outputs the driving pulse Pu. In a case where the switch element 41 is turned off, signal PWM falls at time t51. The waveform shaping circuit 55 generates and outputs the driving pulse Pu similarly to the case where the switch element 41 is turned on.

Since the count value Cnt of the signal CLK has not reached the addition value Vad in the period from time t51 to time t52, the counter 53 outputs the signal Sg1 indicating the first value. Therefore, the MUX 51 selects the counter 53.

At time t52, in a case where the count value Cnt of the signal CLK reaches the addition value Vad, the counter 53 outputs the signal Sg1 indicating the second value. As a result, the waveform shaping circuit 55 generates and outputs the driving pulse Pu. The period from time t51 to time t52 corresponds to the parameter PM2. That is, at time t52, the first driving period T1 ends. In a case where the switch element 41 is turned off, the waveform shaping circuit 55 generates and outputs the driving pulse Pu at time t52 similarly to the case where the switch element 41 is turned on.

Since the count value Cnt of the signal CLK has reached the addition value Vad from time t52 to time t53, the counter 53 outputs the signal Sg1 indicating the second value. Therefore, the MUX 51 selects the counter 54. In addition, since the count value Cnt of the signal CLK has not reached the value of the parameter PM4 in the period from time t52 to time t53, the counter 54 does not output the signal Sg2.

At time t53, in a case where the count value Cnt of the signal CLK reaches the value of the parameter PM4, the counter 54 outputs the signal Sg2. As a result, the waveform shaping circuit 55 generates and outputs the driving pulse Pu. The period from time t52 to time t53 corresponds to the parameter PM4. That is, the brake period Tb ends at time t53. In a case where the switch element 41 is turned off, the waveform shaping circuit 55 generates and outputs the driving pulse Pu at time t53 similarly to the case where the switch element 41 is turned on.

### 1.2 Active Gate Control Operation

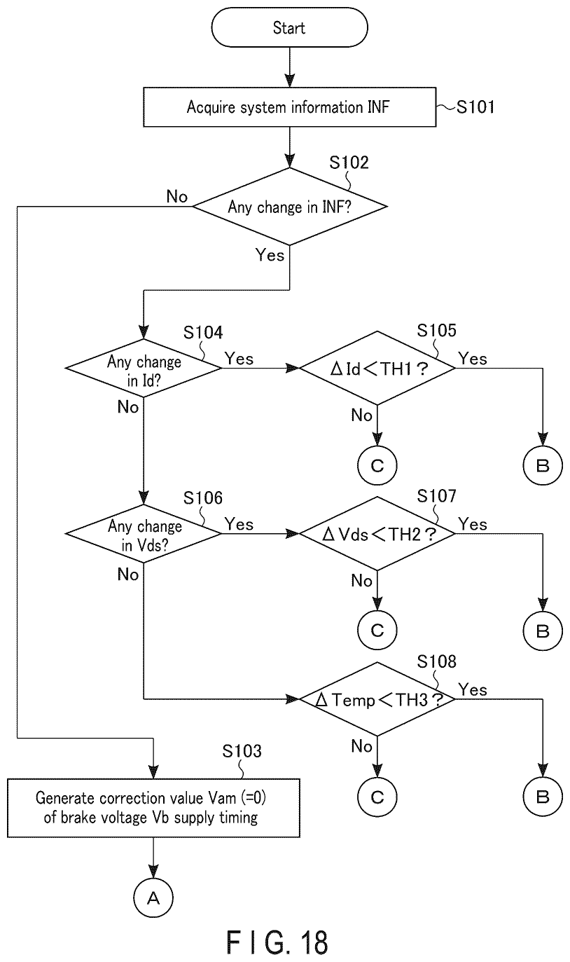

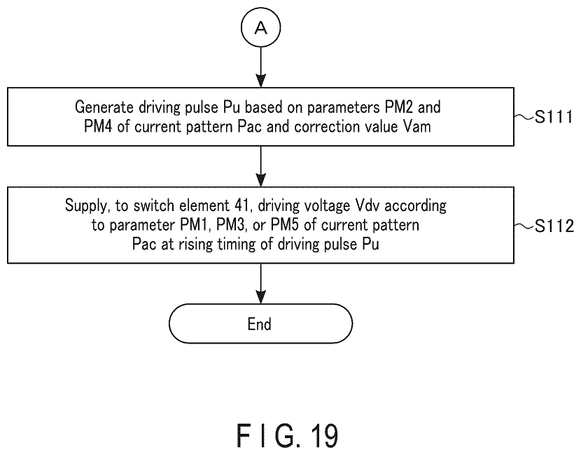

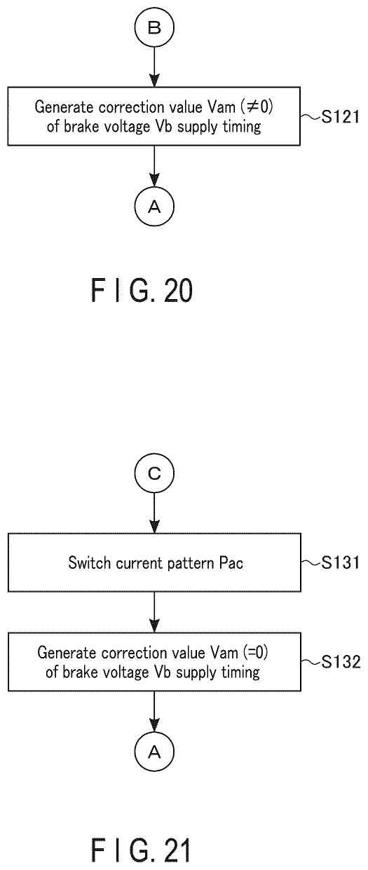

The active gate control operation of the semiconductor device 1 according to the first embodiment will be described. FIGS. 18 to 21 are flowcharts showing an example of the active gate control operation. Hereinafter, a case where the switch element 41 is turned on will be described as an example. The same applies to a case where the switch element 41 is turned off. The “turn-on” can be replaced with “turn-off” in the following description for the case where the switch element 41 is turned off.

For example, in a case where the signal PWM rises at the timing when the switch element 41 is turned on, the acquisition unit 301 acquires the system information INF from the system 4 (S101), and transmits the acquired system information INF to the determination unit 303.

Next, the determination unit 303 receives the system information INF from the acquisition unit 301, and determines whether the system information INF (any of the drain current Id, the drain voltage Vds, and the temperature Temp) has changed (S102).

In a case where it is determined that the system information INF has not changed (S102_No), the determination unit 303 generates the correction value Vam (=0) of the brake voltage Vb supply timing as described above (S103), and transmits the generated correction value Vam to the generation circuit 34.

Next, the generation circuit 34 receives the correction value Vam from the determination unit 303, and generates the driving pulse Pu based on the parameters PM2 and PM4 of the current pattern Pac and the correction value Vam (S111). The generation circuit 34 transmits the generated driving pulse Pu to the current pattern Pac. At the rising timing of the driving pulse Pu, the parameters PM1, PM3, or PM5 of the current pattern Pac are output to the drive circuit 35.

Next, the drive circuit 35 receives the parameter PM1, PM3, or PM5 of the current pattern Pac at the rising timing of the driving pulse Pu, and supplies the driving voltage Vdv according to the parameter PM1, PM3, or PM5 to the switch element 41 (S112). Specifically, the drive circuit 35 converts the parameter PM1, PM3, or PM5 into a voltage, and then supplies the converted voltage as the driving voltage Vdv to the switch element 41. The waveform of the driving voltage Vdv supplied to the switch element 41 is, for example, as illustrated in FIG. 3. In a case where the switch element 41 is turned off, the waveform of driving voltage Vdv supplied to the switch element 41 is, for example, as illustrated in FIG. 5.

In a case where it is determined that the system information INF has changed (S102_Yes), the determination unit 303 determines whether the drain current Id has changed (S104). In a case where it is determined that the drain current Id has changed (S104_Yes), the determination unit 303 determines whether or not the change amount ΔId of the drain current Id is less than a threshold TH1 (S105). In a case where it is determined that the change amount ΔId is less than the threshold TH1 (S105_Yes), the correction unit 304 generates the correction value Vam (≠0) of the brake voltage Vb supply timing as described above (S121), and transmits the generated correction value Vam to the generation circuit 34. Then, steps S111 and S112 are executed. In a case where it is determined that the change amount ΔId is equal to or greater than the threshold TH1 (S105_No), the switching unit 305 switches the current pattern Pac as described above (S131). Next, as described above, the switching unit 305 generates the correction value Vam (=0) of the brake voltage Vb supply timing (S132), and transmits the generated correction value Vam to the generation circuit 34. Then, steps S111 and S112 are executed.

In a case where it is determined that the drain current Id has not changed (S104_No), the determination unit 303 determines whether the drain voltage Vds has changed (S106). In a case where it is determined that the drain voltage Vds has changed (S106_Yes), the determination unit 303 determines whether the change amount ΔVds of the drain voltage Vds is less than a threshold TH2 (S107). In a case where it is determined that the change amount ΔVds is less than the threshold TH2 (S107_Yes), the correction unit 304 generates the correction value Vam (≠0) of the brake voltage Vb supply timing as described above (S121), and transmits the generated correction value Vam to the generation circuit 34. Then, steps S111 and S112 are executed. In a case where it is determined that the change amount ΔVds is equal to or greater than the threshold TH2 (S107_No), the switching unit 305 switches the current pattern Pac as described above (S131). Next, as described above, the switching unit 305 generates the correction value Vam (=0) of the brake voltage Vb supply timing (S132), and transmits the generated correction value Vam to the generation circuit 34. Then, steps S111 and S112 are executed.

In a case where it is determined that the drain voltage Vds has not changed (S106_No), the determination unit 303 determines whether or not the change amount ΔTemp of the temperature Temp is less than a threshold TH3 (S108). In a case where it is determined that the change amount ΔTemp is less than the threshold TH3 (S108_Yes), the correction unit 304 generates the correction value Vam (≠0) of the brake voltage Vb supply timing as described above (S121), and transmits the generated correction value Vam to the generation circuit 34. Then, steps S111 and S112 are executed. In a case where it is determined that the change amount ΔTemp is equal to or greater than the threshold TH3 (S108_No), the switching unit 305 switches the current pattern Pac as described above (S131). Next, as described above, the switching unit 305 generates the correction value Vam (=0) of the brake voltage Vb supply timing (S132), and transmits the generated correction value Vam to the generation circuit 34. Then, steps S111 and S112 are executed.

The thresholds TH1 to TH3 depend on the characteristics of the switch element 41. In addition, the thresholds TH1 to TH3 also depend on specifications of the system 4 such as an allowable range of noise, a withstand voltage, and efficiency. Therefore, the thresholds TH1 to TH3 are determined in consideration of these.

After the switch element 41 is turned on and becomes a steady state, the load unit 302 acquires the current pattern Pac corresponding to the system information INF and the six driving patterns Pa adjacent to the current pattern Pac from the 64 driving patterns Pa2 in the lookup table LUT in preparation for a case where the switch element 41 is turned off. Note that, in a case where the switch element 41 is turned off, after the switch element 41 is turned off and becomes a steady state, the load unit 302 acquires the current pattern Pac corresponding to the system information INF and the six driving patterns Pa adjacent to the current pattern Pac from the 64 driving patterns Pa1 in the lookup table LUT in preparation for a case where the switch element 41 is turned on.

### 1.3 Effects According to Present Embodiment

The semiconductor device 1 according to the present embodiment includes the lookup table LUT, the MCU 2, and the gate driver 3.

The lookup table LUT includes the driving patterns Pa according to the changes in the system information INF of the switch element 41. The driving patterns Pa are based on the combinations of the drain current Id, the drain voltage Vds, and the temperature Temp. The driving pattern Pa includes the parameter PM1 corresponding to the first driving voltage V1, the parameter PM2 corresponding to the first driving period T1, the parameter PM3 corresponding to the brake voltage Vb, the parameter PM4 corresponding to the brake period Tb, and the parameter PM5 corresponding to the second driving voltage V2.

The MCU 2 stores the lookup table LUT.

The gate driver 3 stores the lookup table LUTg including the current pattern Pac and six driving patterns Pa adjacent to the current pattern Pac among the driving patterns Pa in the lookup table LUT. The lookup table LUTg is loaded from the MCU 2 to the memory 32 in the gate driver 3.

In addition, the gate driver 3 includes the control circuit 31, the generation circuit 34, and the drive circuit 35. The generation circuit 34 generates the driving pulse Pu based on the current pattern Pac. The drive circuit 35 drives the switch element 41 with a voltage based on the current pattern Pac at timing based on the driving pulse Pu.

As described above, in a case where the change in the system information INF is small, the appropriate driving pattern Pa becomes a pattern similar to the current pattern Pac. Furthermore, in a case where the change in the system information INF is large, the appropriate driving pattern Pa becomes a pattern not similar to the current pattern Pac.

Therefore, in the present embodiment, in a case where the change amount Δ in the system information INF of the switch element 41 is less than the threshold at the timing when the switch element 41 is turned on or off, the control circuit 31 generates the correction value Vam of the brake voltage Vb supply timing, and the generation circuit 34 generates the driving pulse Pu based on the current pattern Pac and the correction value Vam. On the other hand, in a case where the change amount Δ in the system information INF of the switch element 41 is equal to or greater than the threshold, the control circuit 31 replaces the current pattern Pac with one driving pattern Pa adjacent to the current pattern Pac, and the generation circuit 34 generates the driving pulse Pu based on the replaced current pattern Pacr.

That is, in a case where the change in the system information INF is small, the switch element 41 is driven by the driving pattern in which the brake voltage Vb supply timing in the current pattern Pac is corrected without switching the current pattern Pac. On the other hand, in a case where the change in the system information INF is large, the current pattern Pac is switched, and the switch element 41 is driven by the switched current pattern Pac. As a result, the number of driving patterns Pa of the lookup table LUTg stored in the memory 32 can be reduced. Therefore, according to the present embodiment, the capacity of the memory 32 of the gate driver 3 can be reduced.

In addition, the parameters PM1 to PM5 included in the driving pattern Pa of the lookup table LUT are appropriate parameters according to the drain current Id, the drain voltage Vds, and the temperature Temp. Therefore, by performing active gate control using the lookup table LUTg loaded from the lookup table LUT, reduction of surge and reduction of conduction loss or switching loss can be realized.

### 2. Second Embodiment

A semiconductor device according to a second embodiment will be described. In a semiconductor device 1 according to the second embodiment, a configuration of a lookup table LUTg is different from that of the first embodiment. Hereinafter, differences from the first embodiment will be described.

### 2.1 Configuration of Lookup Table LUTg

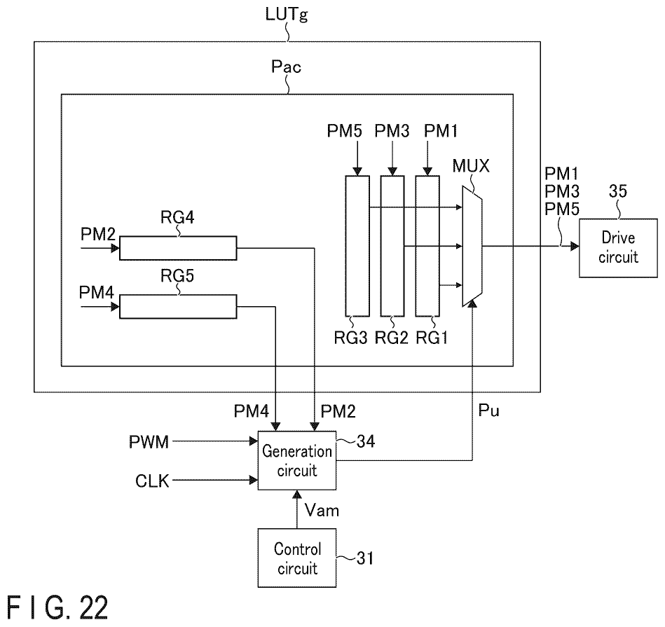

The configuration of the lookup table LUTg of the semiconductor device 1 according to the second embodiment will be described with reference to FIG. 22. FIG. 22 is a diagram illustrating an example of the configuration of the lookup table LUTg of the semiconductor device 1 according to the present embodiment. FIG. 22 illustrates only a current pattern Pac among seven driving patterns Pa in the lookup table LUTg. The other driving patterns Pa in the lookup table LUTg also have the same configuration as the current pattern Pac. FIG. 22 also illustrates the control circuit 31, the generation circuit 34, and the drive circuit 35.

As illustrated in FIG. 22, the current pattern Pac includes registers RG1 to RG5 and an MUX.

The registers RG1 to RG3 are registers RG1, RG2, and RG3 in this order from the right side of the drawing. Each of the registers RG1 to RG3 includes, for example, six flip-flops. The parameter PM1 corresponding to the first driving voltage V1 is stored in the register RG1. The parameter PM3 corresponding to the brake voltage Vb is stored in the register RG2. The parameter PM5 corresponding to the second driving voltage V2 is stored in the register RG3.

Each of the registers RG4 and RG5 includes, for example, five flip-flops. The parameter PM2 corresponding to the first driving period T1 is stored in the register RG4. The parameter PM4 corresponding to the brake period Tb is stored in the register RG5.

The MUX is a circuit that selects one of the registers RG1 to RG3 based on a driving pulse Pu output from the generation circuit 34 and outputs a parameter PM stored in the selected register.

The generation circuit 34 receives the signals CLK and PWM from the MCU 2. The generation circuit 34 acquires the parameters PM2 and PM4 from the current pattern Pac. The generation circuit 34 receives the correction value Vam from the control circuit 31. The generation circuit 34 generates the driving pulse Pu based on the signals CLK and PWM, the parameters PM2 and PM4, and the correction value Vam. The generation circuit 34 transmits the generated driving pulse Pu to the MUX of the current pattern Pac.

The MUX selects one of the registers RG1 to RG3 at the rising timing of the driving pulse Pu, and the parameter PM is output from the selected register to the drive circuit 35. First, the register RG1 is selected, and the parameter PM1 is output from the register RG1 to the drive circuit 35. Next, the register RG2 is selected, and the parameter PM3 is output from the register RG2 to the drive circuit 35. Next, the register RG3 is selected, and the parameter PM5 is output from the register RG3 to the drive circuit 35.

### 2.2 Effects According to Present Embodiment

According to the present embodiment, the same effects as those of the first embodiment are obtained.

### 3. Third Embodiment

A semiconductor device according to a third embodiment will be described. A semiconductor device 1 according to the third embodiment is different from that of the first embodiment in the configuration of the lookup table LUTg and the configuration of the generation circuit 34. Hereinafter, differences from the first embodiment will be described.

### 3.1 Configuration of Lookup Table LUTg

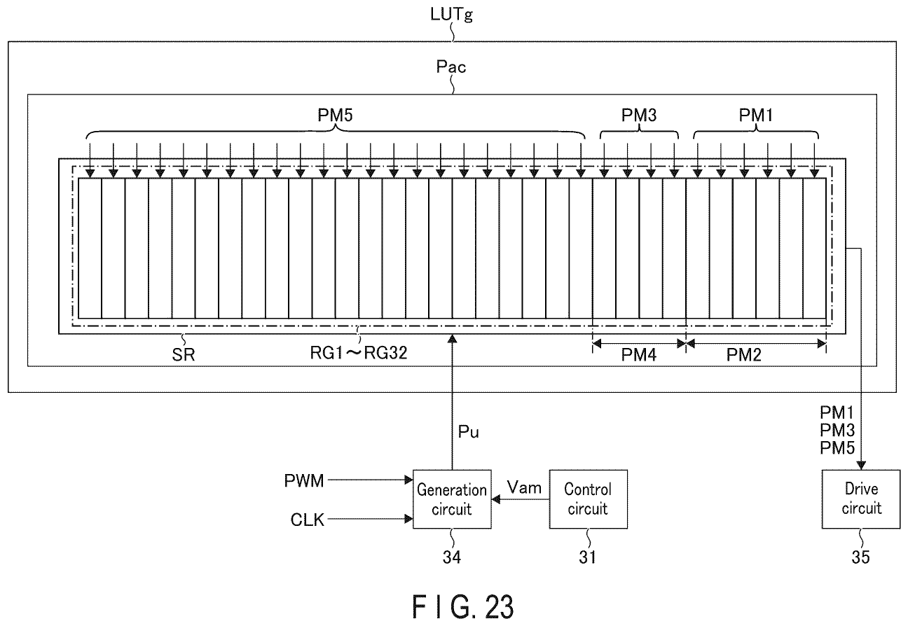

The configuration of the lookup table LUTg of the semiconductor device 1 according to the third embodiment will be described with reference to FIG. 23. FIG. 23 is a diagram illustrating an example of the configuration of the lookup table LUTg of the semiconductor device 1 according to the present embodiment. FIG. 23 illustrates only a current pattern Pac among seven driving patterns Pa in the lookup table LUTg. The other driving patterns Pa in the lookup table LUTg also have the same configuration as the current pattern Pac. FIG. 23 also illustrates the control circuit 31, the generation circuit 34, and the drive circuit 35.

As illustrated in FIG. 23, the current pattern Pac includes registers RG1 to RG32.

The registers RG1 to RG32 are registers RG1, RG2, . . . , RG31, and RG32 in this order from the right side of the drawing. The registers RG1 to RG32 hold parameters PM up to a next turn-on or turn-off by the signal PWM. Each of the registers RG1 to RG32 includes, for example, six flip-flops. Each of the registers RG1 to RG6 stores the parameter PM1 corresponding to the first driving voltage V1. Each of the registers RG7 to RG10 stores the parameter PM3 corresponding to the brake voltage Vb. Each of the registers RG11 to RG32 stores the parameter PM5 corresponding to the second driving voltage V2. The registers RG1 to RG32 constitute a shift register SR.

The generation circuit 34 receives the signals CLK and PWM from the MCU 2. The generation circuit 34 receives the correction value Vam from the control circuit 31. The generation circuit 34 generates the driving pulse Pu based on the signals CLK and PWM and the correction value Vam. The generation circuit 34 transmits the generated driving pulse Pu to the shift register SR of the current pattern Pac.

The shift register SR shifts the values stored in the registers RG1 to RG32 at a rising timing of the driving pulse Pu, and the parameter PM is output from the register RG1 to the drive circuit 35. First, the parameter PM1 is output from the register RG1 to the drive circuit 35 six times. Next, the parameter PM3 is output from the register RG1 to the drive circuit 35 four times. Next, the parameter PM5 is output from the register RG1 to the drive circuit 35 22 times.

### 3.2 Configuration of Generation Circuit

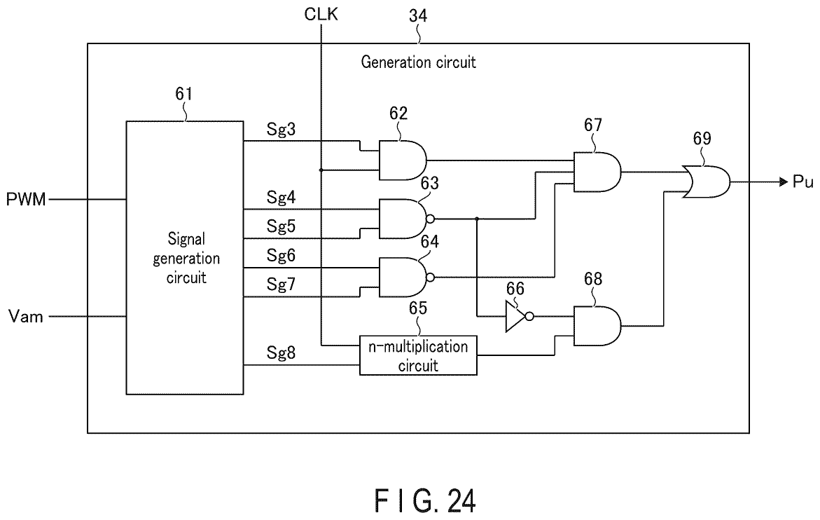

A configuration of the generation circuit 34 of the semiconductor device 1 according to the third embodiment will be described with reference to FIG. 24. FIG. 24 is a circuit diagram showing an example of a configuration of the generation circuit 34 of the semiconductor device 1 according to the present embodiment.

As illustrated in FIG. 24, the generation circuit 34 includes a signal generation circuit 61, AND circuits 62, 67, and 68, NAND circuits 63 and 64, an n-multiplication circuit 65 (n is an integer of 2 or more), an inverter circuit 66, and an OR circuit 69.

The signal generation circuit 61 is a circuit that generates a signal based on the signal PWM and a signal based on a correction value Vam. The signal generation circuit 61 outputs a signal Sg3 at an “H” (High) level at a rising or falling timing of the signal PWM. The signal Sg3 is input to the AND circuit 62. In addition, the signal generation circuit 61 outputs signals Sg4 to Sg8 based on the value of the correction value Vam. The signal Sg4 is a signal indicating that the brake voltage Vb supply timing is advanced. The signal Sg5 is a signal for controlling a length of the first driving period T1 in a case where the brake voltage Vb supply timing is advanced. The signals Sg4 and Sg5 are input to the NAND circuit 63. The signal Sg6 is a signal indicating that the brake voltage Vb supply timing is delayed. The signal Sg7 is a signal for controlling the length of the first driving period T1 in a case where the brake voltage Vb supply timing is delayed. The signals Sg6 and Sg7 are input to the NAND circuit 64. The signal Sg8 is a signal indicating generation of a signal in which the frequency of the signal CLK is multiplied by n. The signal Sg8 is input to the n-multiplication circuit 65.

For example, in a case where the correction value Vam is 0, the signal generation circuit 61 outputs the signals Sg4 to Sg7 at a “L” (Low) level. The signal generation circuit 61 outputs the signal Sg8 in which n is set to 1.

In a case where the correction value Vam is a negative value, the signal generation circuit 61 outputs the signal Sg4 at the “H” level and the signals Sg6 and Sg7 at the “L” level. The signal generation circuit 61 determines a period based on the magnitude of the absolute value of the correction value Vam, outputs the signal Sg5 at the “H” level during the determined period, and outputs the signal Sg5 at the “L” level during other periods. The signal generation circuit 61 outputs the signal Sg8 in which n is an integer of 2 or more (a value corresponding to the determined period).

In a case where the correction value Vam is a positive value, the signal generation circuit 61 outputs the signals Sg4 and Sg5 at the “L” level and the signal Sg6 at the “H” level. The signal generation circuit 61 determines a period based on the magnitude of the absolute value of the correction value Vam, outputs the signal Sg7 at the “H” level during the determined period, and outputs the signal Sg7 at the “L” level during other periods. The signal generation circuit 61 outputs the signal Sg8 in which n is set to 1.

The AND circuit 62 receives the signals CLK and Sg3 and outputs a result of an AND operation of the signals CLK and Sg3 to the AND circuit 67.

The NAND circuit 63 receives the signals Sg4 and Sg5 and outputs the results of the NAND operation of the signals Sg4 and Sg5 to the inverter circuit 66 and the AND circuit 67.

The NAND circuit 64 receives the signals Sg6 and Sg7 and outputs a result of the NAND operation of the signals Sg6 and Sg7 to the AND circuit 67.

The n-multiplication circuit 65 is a circuit that generates a signal obtained by multiplying the frequency of the signal CLK by n based on the signal Sg8. The generated signal is output to the AND circuit 68. For example, in a case where the correction value Vam is 0 or a positive value, the n-multiplication circuit 65 outputs the signal CLK as it is based on the signal Sg8. In a case where the correction value Vam is a negative value, the n-multiplication circuit 65 outputs a signal obtained by multiplying the frequency of the signal CLK by n based on the signal Sg8.

The inverter circuit 66 receives the operation result of the NAND circuit 63, and outputs a signal obtained by inverting the logic level of the operation result to the AND circuit 68.

The AND circuit 67 receives the operation result of the AND circuit 62, the operation result of the NAND circuit 63, and the operation result of the NAND circuit 64, and outputs a result of the AND operation of these operation results to the OR circuit 69.

The AND circuit 68 receives the signal output from the inverter circuit 66 and the signal output from the n-multiplication circuit 65, and outputs a result of the AND operation of these signals to the OR circuit 69.

The OR circuit 69 receives the operation result of the AND circuit 67 and the operation result of the AND circuit 68, and outputs a result of the OR operation of these operation results as the driving pulse Pu.

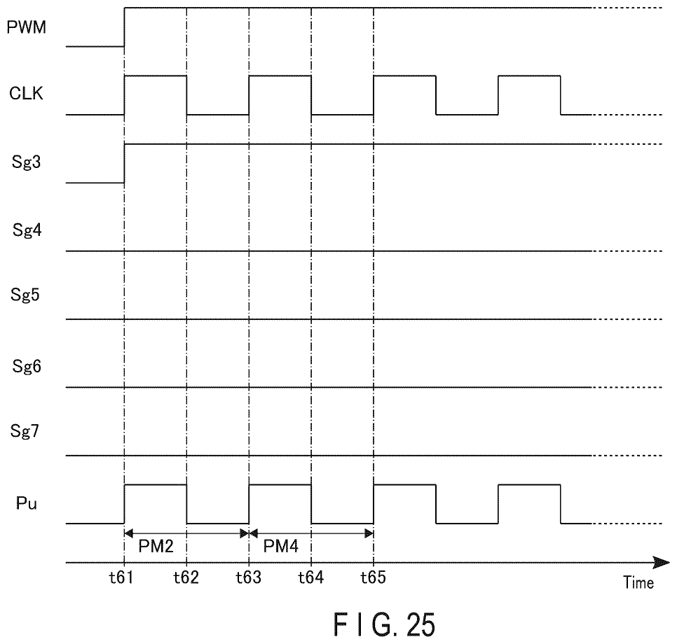

FIG. 25 is a diagram showing an example of a waveform of the driving pulse Pu generated by the generation circuit 34 of the semiconductor device 1 according to the present embodiment. FIG. 25 illustrates a waveform in a case where the switch element 41 is turned on. The example of FIG. 25 is a case where the correction value Vam is 0, that is, a case where the brake voltage Vb supply timing is not corrected. Before time t61, the signals Sg3 to Sg7 are at the “L” level.

At time t61, the signals PWM and CLK rise. The signal Sg3 becomes the “H” level. The operation result of the AND circuit 62 is the “H” level. The operation result of the NAND circuit 63 is the “H” level. The operation result of the NAND circuit 64 is the “H” level. The n-multiplication circuit 65 outputs the signal CLK. The signal output from the inverter circuit 66 is at the “L” level. The operation result of the AND circuit 67 is the “H” level. The operation result of the AND circuit 68 is the “L” level. The operation result of the OR circuit 69 is the “H” level. As a result, the driving pulse Pu output from the OR circuit 69 becomes the “H” level. In a case where switch element 41 is turned off, the signal PWM falls at time t61. The driving pulse Pu output from the OR circuit 69 becomes the “H” level similarly to the case where the switch element 41 is turned on.

At time t62, the signal CLK falls. The operation result of the AND circuit 62 is the “L” level. The operation result of the AND circuit 67 is the “L” level. The operation result of the AND circuit 68 is the “L” level. The operation result of the OR circuit 69 is the “L” level. As a result, the driving pulse Pu output from the OR circuit 69 becomes the “L” level.

At time t63, the signal CLK rises. The operation result of the AND circuit 62 is the “H” level. The operation result of the AND circuit 67 is the “H” level. The operation result of the AND circuit 68 is the “L” level. The operation result of the OR circuit 69 is the “H” level. As a result, the driving pulse Pu output from the OR circuit 69 becomes the “H” level. The period from time t61 to time t63 corresponds to the parameter PM2. That is, the first driving period T1 ends at time t63. In a case where the switch element 41 is turned off, the driving pulse Pu output from the OR circuit 69 becomes the “H” level at time t63, similarly to the case where the switch element 41 is turned on.

At time t64, the signal CLK falls. The operation result of the AND circuit 62 is the “L” level. The operation result of the AND circuit 67 is the “L” level. The operation result of the AND circuit 68 is the “L” level. The operation result of the OR circuit 69 is the “L” level. As a result, the driving pulse Pu output from the OR circuit 69 becomes the “L” level.

At time t65, the signal CLK rises. The operation result of the AND circuit 62 is the “H” level. The operation result of the AND circuit 67 is the “H” level. The operation result of the AND circuit 68 is the “L” level. The operation result of the OR circuit 69 is the “H” level. As a result, the driving pulse Pu output from the OR circuit 69 becomes the “H” level. The period from time t63 to time t65 corresponds to the parameter PM4. That is, the brake period Tb ends at time t65. In a case where the switch element 41 is turned off, the driving pulse Pu output from the OR circuit 69 becomes the “H” level at time t65, similarly to the case where the switch element 41 is turned on.

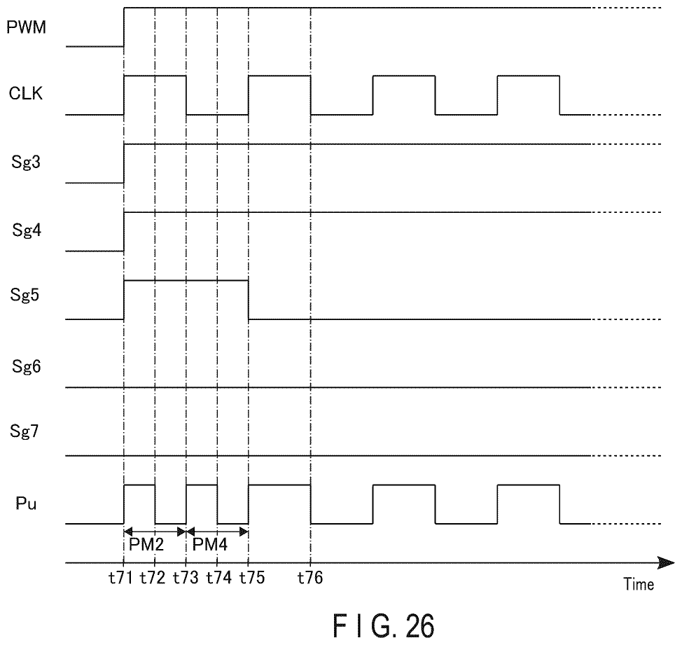

FIG. 26 is a diagram showing an example of a waveform of the driving pulse Pu generated by the generation circuit 34 of the semiconductor device 1 according to the present embodiment. FIG. 26 illustrates a waveform in a case where the switch element 41 is turned on. The example of FIG. 26 is a case where the correction value Vam is a negative value, that is, a case where the brake voltage Vb supply timing is advanced. In the example of FIG. 26, the n-multiplication circuit 65 is a 2-multiplication circuit. Before time t71, the signals Sg3 to Sg7 are at the “L” level.

At time t71, the signals PWM and CLK rise. The signals Sg3 to Sg5 become the “H” level. The operation result of the AND circuit 62 is the “H” level. The operation result of the NAND circuit 63 is the “L” level. The operation result of the NAND circuit 64 is at the “H” level. The n-multiplication circuit 65 outputs an “H” level signal. The signal output from the inverter circuit 66 is at the “H” level. The operation result of the AND circuit 67 is the “L” level. The operation result of the AND circuit 68 is the “H” level. The operation result of the OR circuit 69 is the “H” level. As a result, the driving pulse Pu output from the OR circuit 69 becomes the “H” level. In a case where the switch element 41 is turned off, the signal PWM falls at time t71. The driving pulse Pu output from the OR circuit 69 becomes the “H” level similarly to the case where the switch element 41 is turned on.

At time t72, the n-multiplication circuit 65 outputs a signal at the “L” level. The operation result of the AND circuit 67 is the “L” level. The operation result of the AND circuit 68 is the “L” level. The operation result of the OR circuit 69 is the “L” level. As a result, the driving pulse Pu output from the OR circuit 69 becomes the “L” level.

At time t73, the signal CLK falls. The operation result of the AND circuit 62 is the “L” level. The n-multiplication circuit 65 outputs a signal at the “H” level. The operation result of the AND circuit 67 is the “L” level. The operation result of the AND circuit 68 is the “H” level. The operation result of the OR circuit 69 is the “H” level. As a result, the driving pulse Pu output from the OR circuit 69 becomes the “H” level. The period from time t71 to time t73 corresponds to the parameter PM2. That is, the first driving period T1 ends at time t73. In a case where the switch element 41 is turned off, the driving pulse Pu output from the OR circuit 69 becomes the “H” level at time t73, similarly to the case where the switch element 41 is turned on.

At time t74, the n-multiplication circuit 65 outputs a signal at the “L” level. The operation result of the AND circuit 67 is the “L” level. The operation result of the AND circuit 68 is the “L” level. The operation result of the OR circuit 69 is the “L” level. As a result, the driving pulse Pu output from the OR circuit 69 becomes the “L” level.

At time t75, the signal CLK rises. The signal Sg5 becomes the “L” level. The operation result of the AND circuit 62 is the “H” level. The operation result of the NAND circuit 63 becomes the “H” level. The signal output from the inverter circuit 66 is at the “L” level. The operation result of the AND circuit 67 is the “H” level. The operation result of the AND circuit 68 is the “L” level. The operation result of the OR circuit 69 is the “H” level. As a result, the driving pulse Pu output from the OR circuit 69 becomes the “H” level. The period from time t73 to time t75 corresponds to the parameter PM4. That is, the brake period Tb ends at time t75. In a case where the switch element 41 is turned off, the driving pulse Pu output from the OR circuit 69 becomes the “H” level at time t75, similarly to the case where the switch element 41 is turned on.

At time t76, the signal CLK falls. The operation result of the AND circuit 62 is the “L” level. The operation result of the AND circuit 67 is the “L” level. The operation result of the AND circuit 68 is the “L” level. The operation result of the OR circuit 69 is the “L” level. As a result, the driving pulse Pu output from the OR circuit 69 becomes the “L” level.

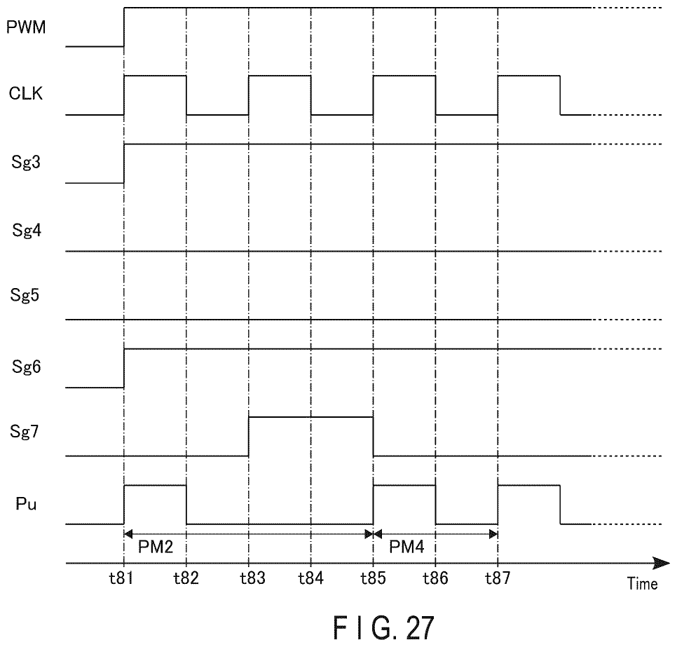

FIG. 27 is a diagram showing an example of a waveform of the driving pulse Pu generated by the generation circuit 34 of the semiconductor device 1 according to the present embodiment. FIG. 27 illustrates a waveform in a case where the switch element 41 is turned on. The example of FIG. 27 is a case where the correction value Vam is a positive value, that is, a case where the brake voltage Vb supply timing is delayed. Before time t81, the signals Sg3 to Sg7 are at the “L” level.

At time t81, the signals PWM and CLK rise. The signals Sg3 and Sg6 become the “H” level. The operation result of the AND circuit 62 is the “H” level. The operation result of the NAND circuit 63 is the “H” level. The operation result of the NAND circuit 64 is the “H” level. The n-multiplication circuit 65 outputs a signal CLK. The signal output from the inverter circuit 66 is at the “L” level. The operation result of the AND circuit 67 is the “H” level. The operation result of the AND circuit 68 is the “L” level. The operation result of the OR circuit 69 is the “H” level. As a result, the driving pulse Pu output from the OR circuit 69 becomes the “H” level. In a case where the switch element 41 is turned off, the signal PWM falls at time t81. The driving pulse Pu output from the OR circuit 69 becomes the “H” level similarly to the case where the switch element 41 is turned on.

At time t82, the signal CLK falls. The operation result of the AND circuit 62 is the “L” level. The operation result of the AND circuit 67 is the “L” level. The operation result of the AND circuit 68 is the “L” level. The operation result of the OR circuit 69 is the “L” level. As a result, the driving pulse Pu output from the OR circuit 69 becomes the “L” level.

At time t83, the signal CLK rises. The signal Sg7 becomes the “H” level. The operation result of the AND circuit 62 is the “H” level. The operation result of the NAND circuit 64 is the “L” level. The operation result of the AND circuit 67 is the “L” level. The operation result of the AND circuit 68 is the “L” level. The operation result of the OR circuit 69 is the “L” level. As a result, the driving pulse Pu output from the OR circuit 69 becomes the “L” level.

At time t84, the signal CLK falls. The operation result of the AND circuit 62 is the “L” level. The operation result of the AND circuit 67 is the “L” level. The operation result of the AND circuit 68 is the “L” level. The operation result of the OR circuit 69 is the “L” level. As a result, the driving pulse Pu output from the OR circuit 69 becomes the “L” level.

At time t85, the signal CLK rises. The signal Sg7 becomes the “L” level. The operation result of the AND circuit 62 is the “H” level. The operation result of the NAND circuit 64 becomes the “H” level. The operation result of the AND circuit 67 is the “H” level. The operation result of the AND circuit 68 is the “L” level. The operation result of the OR circuit 69 is the “H” level. As a result, the driving pulse Pu output from the OR circuit 69 becomes the “H” level. The period from time t81 to time t85 corresponds to the parameter PM2. That is, the first driving period T1 ends at time t85. In a case where the switch element 41 is turned off, the driving pulse Pu output from the OR circuit 69 becomes the “H” level at time t85, similarly to the case where the switch element 41 is turned on.

At time t86, the signal CLK falls. The operation result of the AND circuit 62 is the “L” level. The operation result of the AND circuit 67 is the “L” level. The operation result of the AND circuit 68 is the “L” level. The operation result of the OR circuit 69 is the “L” level. As a result, the driving pulse Pu output from the OR circuit 69 becomes the “L” level.

At time t87, the signal CLK rises. The signal Sg7 becomes the “L” level. The operation result of the AND circuit 62 is the “H” level. The operation result of the NAND circuit 64 becomes the “H” level. The operation result of the AND circuit 67 is the “H” level. The operation result of the AND circuit 68 is the “L” level. The operation result of the OR circuit 69 is the “H” level. As a result, the driving pulse Pu output from the OR circuit 69 becomes the “H” level. The period from time t85 to time t87 corresponds to the parameter PM4. That is, the brake period Tb ends at time t87. In a case where the switch element 41 is turned off, the driving pulse Pu output from the OR circuit 69 becomes the “H” level at time t87, similarly to the case where the switch element 41 is turned on.

### 3.3 Active Gate Control Operation

An active gate control operation of the semiconductor device 1 according to the third embodiment will be described. A flowchart illustrating an example of the active gate control operation of the semiconductor device 1 according to the present embodiment is similar to those in FIGS. 18 to 21 of the first embodiment except that step S111 is replaced with the following process. In step S111, the generation circuit 34 receives the correction value Vam from the determination unit 303, the correction unit 304, or the switching unit 305, and generates the driving pulse Pu based on the correction value Vam.

### 3.4 Effects According to Present Embodiment

According to the present embodiment, the same effects as those of the first embodiment are obtained.

### 4. Modifications and Others

As described above, a semiconductor device (1) according to the embodiment includes a first table (LUT) including a plurality of driving patterns (Pa), a controller (2) including the first table, and a driver (3). The driver (3) includes a second table (LUTg) including at least a first pattern (Pac) and a second pattern (Pa) of the plurality of the driving patterns (Pa) in the first table (LUT), a control circuit (31), a generation circuit (34) that generates a driving pulse (Pu) based on the first pattern, and a drive circuit (35) that drives a switch element (41) by a voltage (Vdv) or a current (Idv) based on the first pattern at a timing based on the driving pulse. At a timing when the switch element (41) is turned on or off, in a case where a change amount (Δ) of first information (Id/Vds/Temp) of the switch element is less than a first threshold (TH1/TH2/TH3), the control circuit (31) generates a correction value (Vam), and the generation circuit (34) generates the driving pulse (Pu) based on the first pattern (Pac) and the correction value, and in a case where the change amount of the first information of the switch element is equal to or greater than the first threshold, the control circuit (31) replaces the first pattern (Pac) with the second pattern (Pas), and the generation circuit (34) generates the driving pulse (Pu) based on the replaced first pattern (Pacr).

Note that the embodiments are not limited to the above-described manner, and various modifications are possible.

In the flowcharts described in the above embodiments, the order of the processes can be changed as much as possible.

In the above embodiments, the cases where the switch element 41 in the system 4 is controlled by the voltage has been described as examples, but any of the above embodiments is also applicable to a case where the switch element 41 is controlled by current (current drive). That is, the driving pattern Pa may not be defined by voltage and time, but may be defined by current and time. In other words, in the driving pattern Pa described above, the voltage can be replaced with a current. For example, in the case of current driving, the “driving voltage Vdv” is replaced with the “driving current Idv” in FIGS. 1, 3, 5 to 11, 14, and 19. The “first driving voltage V1” is replaced with “first driving current I1”. The “brake voltage Vb” is replaced with a “brake current Ib”. The “second driving voltage V2” is replaced with the “second driving current I2”. The first driving current I1 is a current supplied to the gate of the switch element 41 for turning on or off. In a case where the switch element 41 is turned on and turned off, the brake current Ib is lower than the first driving current I1. In FIGS. 12 to 27, the parameter PM1 of the driving pattern Pa is replaced with “a parameter corresponding to the first driving current I1”, the parameter PM3 of the driving pattern Pa is replaced with “a parameter corresponding to the brake current Ib”, and the parameter PM5 of the driving pattern Pa is replaced with “a parameter corresponding to the second driving current I2”. The generation circuit 34 generates a driving pulse Pu for controlling the timing of supplying the driving current Idv to the gate of the switch element 41 based on the driving pattern Pa (current pattern Pac) stored in the RAM in the memory 32. The drive circuit 35 drives the switch element 41 by the current based on the driving pattern Pa (current pattern Pac) stored in the RAM in the memory 32 at the timing based on the driving pulse Pu.

In the first embodiment, the adder 52 and the counter 53 of the generation circuit 34 may be replaced with an up/down counter. In this case, the up/down counter generates an addition value Vad obtained by increasing or decreasing the value of the parameter PM2 by the value of the correction value Vam. The up/down counter outputs the first value as the signal Sg1 in a case where the count value Cnt does not reach the addition value Vad, and outputs the second value as the signal Sg1 in a case where the count value Cnt reaches the addition value Vad.

In addition, the number of driving patterns Pa included in the lookup table LUTg stored in the memory 32 may not be seven, and may be, for example, three. In this case, for example, Current pattern Pac(ic, jc, kc) and Driving pattern Pa(ic±1, jc, kc) may be used, Current pattern Pac(ic, jc, kc) and Driving pattern Pa(ic, jc±1, kc) may be used, or Current pattern Pac(ic, jc, kc) and Driving pattern Pa(ic, jc, kc±1) may be used.

For example, upon receiving the type CL and the change amount Δ from the determination unit 303, the switching unit 305 determines one driving pattern Pa (switching pattern Pas) to be switched to the current pattern Pac among the two driving patterns Pa adjacent to the current pattern Pac. The switching unit 305 transmits the determined switching pattern Pas to the lookup table LUTg and switches the current pattern Pac in the lookup table LUTg to the switching pattern Pas. As a result, the current pattern Pac and one driving pattern Pa adjacent to the current pattern Pac are stored in the memory 32.

It is considered a case where the two driving patterns Pa adjacent to the current pattern Pac are Driving patterns Pa(ic±1, jc, kc), the switch element 41 is turned on or off, and the drain current Id, the drain voltage Vds, or the temperature Temp rises (change amount ΔId>0). In this case, the switching unit 305 determines Driving pattern Pa(ic+1, jc, kc) as the switching pattern Pas.

In a case where the two driving patterns Pa adjacent to the current pattern Pac are Driving patterns Pa(ic±1, jc, kc), the switch element 41 is turned on or off, and the drain current Id, the drain voltage Vds, or the temperature Temp drops (change amount ΔId<0), the switching unit 305 determines Driving pattern Pa(ic−1, jc, kc) as the switching pattern Pas.

The same applies to a case where the two driving patterns Pa adjacent to the current pattern Pac are Driving patterns Pa(ic, jc±1, kc) and a case where the two driving patterns Pa adjacent to the current pattern Pac are Driving patterns Pa(ic, jc, kc±1).

In the present specification, “connection” indicates electrical connection, and for example, it is not excluded that another element is interposed therebetween.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first table including a plurality of driving patterns;
a controller including the first table; and
a driver that includes
a second table including at least a first pattern and a second pattern of the plurality of the driving patterns in the first table,
a control circuit,
a generation circuit that generates a driving pulse based on the first pattern, and
a drive circuit that drives a switch element by a voltage or a current based on the first pattern at a timing based on the driving pulse, wherein
at a timing when the switch element is turned on or turned off,
in a case where a change amount of first information of the switch element is less than a first threshold, the control circuit generates a correction value, and the generation circuit generates the driving pulse based on the first pattern and the correction value, and
in a case where the change amount of the first information of the switch element is equal to or greater than the first threshold, the control circuit replaces the first pattern with the second pattern, and the generation circuit generates the driving pulse based on the replaced first pattern.

2. The device according to claim 1, wherein
the plurality of the driving patterns includes a first driving pattern in a case where the switch element is turned on and a second driving pattern in a case where the switch element is turned off.

3. The device according to claim 1, wherein
each of the plurality of the driving patterns is based on a combination of a drain current, a drain voltage, and a temperature of the switch element.

4. The device according to claim 3, wherein
the second table includes
a third pattern based on a combination of a first drain current, a first drain voltage, and a first temperature,
a fourth pattern based on a combination of a second drain current higher than the first drain current, the first drain voltage, and the first temperature,
a fifth pattern based on a combination of a third drain current lower than the first drain current, the first drain voltage, and the first temperature,
a sixth pattern based on a combination of the first drain current, a second drain voltage higher than the first drain voltage, and the first temperature,
a seventh pattern based on a combination of the first drain current, a third drain voltage lower than the first drain voltage, and the first temperature,
an eighth pattern based on a combination of the first drain current, the first drain voltage, and a second temperature higher than the first temperature, and
a ninth pattern based on a combination of the first drain current, the first drain voltage, and a third temperature lower than the first temperature, wherein
the first pattern is the third pattern, and
the second pattern is any one of the fourth pattern to the ninth pattern.

5. The device according to claim 1 wherein
each of the plurality of the driving patterns includes a first parameter corresponding to a first voltage, a second parameter corresponding to a first period in which the first voltage is supplied, a third parameter corresponding to a second voltage supplied after the first period, a fourth parameter corresponding to a second period in which the second voltage is supplied, and a fifth parameter corresponding to a third voltage supplied after the second period.

6. The device according to claim 5 wherein
the first voltage is a voltage supplied to a gate of the switch element to turn-on or turn-off.

7. The device according to claim 5 wherein
in a case where the switch element is turned on, the second voltage is lower than the first voltage.

8. The device according to claim 5 wherein
in a case where the switch element is turned off, the second voltage is higher than the first voltage.

9. The device according to claim 5 wherein
in a case where the change amount of the first information of the switch element is less than the first threshold, the generation circuit generates the driving pulse based on the second parameter and the fourth parameter of the first pattern and the correction value, and
in a case where the change amount of the first information of the switch element is equal to or greater than the first threshold, the generation circuit generates the driving pulse based on the second parameter and the fourth parameter of the replaced first pattern.

10. The device according to claim 5 wherein
each of the plurality of the driving patterns includes a first register that stores the first parameter, a second register that stores the second parameter, a third register that stores the third parameter, a fourth register that stores the fourth parameter, and a fifth register that stores the fifth parameter, and
the first register, the second register, and the third register constitute a shift register.

11. The device according to claim 1 wherein
each of the plurality of the driving patterns includes a first parameter corresponding to a first current, a second parameter corresponding to a first period in which the first current is supplied, a third parameter corresponding to a second current supplied after the first period, a fourth parameter corresponding to a second period in which the second current is supplied, and a fifth parameter corresponding to a third current supplied after the second period.

12. The device according to claim 11 wherein
the first current is a current supplied to a gate of the switch element to turn-on or turn-off.

13. The device according to claim 11 wherein
in a case where the switch element is turned on and a case where the switch element is turned off, the second current is lower than the first current.

14. The device according to claim 1 wherein
the first pattern is a driving pattern in which a transition is expected at a timing when the switch element is turned on or turned off based on the first information.

15. The device according to claim 14 wherein
the second pattern is a driving pattern corresponding to a case where the first information is increased or decreased from the first pattern.

16. The device according to claim 1 wherein
the first information is a drain current, a drain voltage, or a temperature of the switch element.

17. The device according to claim 1 wherein
the correction value is generated based on the change amount of the first information.

18. The device according to claim 1 wherein
the switch element is a metal oxide semiconductor field effect transistor (MOSFET) or an insulated gate bipolar transistor (IGBT).

19. The device according to claim 1 wherein the switch element is a silicon carbide (SiC) MOSFET.
